(19) United States
(12) Patent Application Publication
(10) Pub. No.: US 2026/0046998 A1
(43) Pub. Date: Feb. 12, 2026

(54) ELECTRONIC DEVICE COMPRISING PRINTED CIRCUIT BOARD INCLUDING THERMAL INTERFACE MATERIAL

(71) Applicant: Samsung Electronics Co., Ltd., Suwon-si (KR)

(72) Inventors: Haejin LEE, Suwon-si (KR); Min PARK, Suwon-si (KR); Jeonggen YOON, Suwon-si (KR); Chorim KIM, Suwon-si (KR); Jieun HWANG, Suwon-si (KR)

(21) Appl. No.: 19/361,739

(22) Filed: Oct. 17, 2025

Related U.S. Application Data
(63) Continuation of application No. PCT/KR2024/005176, filed on Apr. 17, 2024.

(30) Foreign Application Priority Data
Apr. 19, 2023 (KR) 10-2023-0051343
Jan. 2, 2024 (KR) 10-2024-0000603
Jan. 16, 2024 (KR) 10-2024-0007061

(51) Int. Cl. H05K 1/02; H05K 1/14; H05K 9/00

(52) U.S. Cl. CPC H05K 1/0203; H05K 1/144; H05K 9/0024; H05K 2201/042; H05K 2201/10378

(57) ABSTRACT

An electronic device is provided. The electronic device includes a housing, a first printed circuit board, a second printed circuit board, an interposer forming a space between the first printed circuit board and the second printed circuit board, a first electronic component disposed on the first printed circuit board, a second electronic component occupying a first area of the space, and a thermal interface material (TIM) included in the space, wherein the second printed circuit board includes a first opening for inserting a nozzle for injecting the TIM, the first opening corresponding to a second area of the space that is different from the first area.

### CROSS-REFERENCE TO RELATED APPLICATION(S)

This application is a continuation application, claiming priority under 35 U.S.C. § 365 (c), of an International application No. PCT/KR2024/005176, filed on Apr. 17, 2024, which is based on and claims the benefit of a Korean patent application number 10-2023-0051343, filed on Apr. 19, 2023, in the Korean Intellectual Property Office, of a Korean patent application number 10-2024-0000603, filed on Jan. 2, 2024, in the Korean Intellectual Property Office, and of an Korean patent application number 10-2024-0007061, filed on Jan. 16, 2024, in the Korean Intellectual Property Office, the disclosure of each of which is incorporated by reference herein in its entirety.

### BACKGROUND

### 1. Field

The disclosure relates to an electronic device including a printed circuit board including a thermal interface material.

### 2. Description of Related Art

An electronic device may include a plurality of electronic components to implement various functions. The plurality of electronic components may generate heat when operating by consuming power. The heat generated from the electronic components may cause deterioration in a function of the electronic device by increasing a temperature of the electronic component. The electronic device may include a component for emitting the heat generated from the electronic component. For example, the electronic device may include a thermal interface material (TIM) configured to transfer heat. The heat generated from the electronic components may be diffused through the TIM.

The above information is presented as background information only to assist with an understanding of the disclosure. No determination has been made, and no assertion is made, as to whether any of the above might be applicable as a prior art with regard to the disclosure.

### SUMMARY

Aspects of the disclosure are to address at least the above-mentioned problems and/or disadvantages and to provide at least the advantages described below. Accordingly, an aspect of the disclosure is to provide an electronic device including a printed circuit board including a thermal interface material.

Additional aspects will be set forth in part in the description which follows and, in part, will be apparent from the description, or may be learned by practice of the presented embodiments.

In accordance with an aspect of the disclosure, an electronic device is provided. The electronic device includes a housing, a first printed circuit board (PCB) disposed in the housing, the first PCB including a first surface facing the first direction, and a second surface facing the second direction, a second PCB, disposed in the housing, spaced apart from the first PCB in the second direction, the second PCB including a third surface facing the first direction, and a fourth surface facing the second direction, an interposer, disposed between the first PCB and the second PCB to electrically connect the first PCB and the second PCB, defining a space between the first PCB and the second PCB, a first electronic component disposed on the first surface of the first PCB, a second electronic component, disposed on the second surface of the first PCB, occupying a first region of the space, and a thermal interface material (TIM) included in the space, wherein the second PCB defines a first opening, corresponding to a second region of the space different from the first region of the space occupied by the second electronic component, for insertion of a nozzle for injection of the TIM.

In accordance with another aspect of the disclosure, an electronic device is provided. The electronic device includes a housing, a first printed circuit board (PCB), a second PCB, disposed in the housing, spaced apart from the first PCB, an interposer, disposed between the first PCB and the second PCB, forming a space between the first PCB and the second PCB. The electronic device includes a thermal interface material (TIM) positioned in the internal volume, wherein the second PCB defines a first through hole, spaced apart from the interposer by a first distance or more, for insertion of a nozzle for injection of the TIM.

In accordance with another aspect of the disclosure, a printed circuit board (PCB) assembly is provided. The PCB assembly includes a first surface facing a first direction, and a second surface facing a second direction opposite to the first direction, a second PCB, spaced apart from the first PCB in the second direction, the second PCB including a third surface facing the first direction, and a fourth surface facing the second direction, wherein the second surface of the first PCB and the third surface of the second PCB face to each other, an interposer, disposed between the first PCB and the second PCB to electrically connect the first PCB and the second PCB, defining an internal volume between the first PCB and the second PCB, a first electronic component disposed on the first surface of the first PCB, the first electronic component exposed to out of the PCB assembly, a second electronic component, disposed on the second surface of the first PCB, occupying a first region of the internal volume, and a thermal interface material (TIM) positioned in the internal volume, wherein the second PCB defines a first opening, corresponding to a second region of the internal volume different from the first region of the internal volume occupied by the second electronic component, for insertion of a nozzle for injection of the TIM.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram of an electronic device in a network environment according to an embodiment of the disclosure;

FIG. 2 illustrates an electronic device according to an embodiment of the disclosure;

FIG. 3 is an exploded perspective view of an electronic device according to an embodiment of the disclosure;

FIG. 4 illustrates a printed circuit board according to an embodiment of the disclosure;

FIG. 5 is a cross-sectional view in which an electronic device is cut along line A-A′ of FIG. 2 according to an embodiment of the disclosure;

FIG. 6A is a front view of a fourth surface of a second printed circuit board according to an embodiment of the disclosure;

FIG. 6B is a front view of a second surface of a first printed circuit board according to an embodiment of the disclosure;

FIGS. 7A and 7B illustrate a process into which a thermal interface material injected according to various embodiments of the disclosure;

FIG. 8 is a graph indicating a temperature change of a first electronic component according to an embodiment of the disclosure;

FIG. 9A is a graph indicating a clock of a first electronic component according to an embodiment of the disclosure;

FIG. 9B is a graph indicating a temperature change of a first electronic component according to an embodiment of the disclosure;

FIG. 9C is a graph indicating an FPS of a display according to an embodiment of the disclosure;

FIG. 10 illustrates an electronic device according to an embodiment according to an embodiment of the disclosure;

FIG. 11A is a front view of a fourth surface of a second printed circuit board according to an embodiment of the disclosure;

FIG. 11B is a front view of a second surface of a first printed circuit board according to an embodiment of the disclosure; and

FIG. 11C is a front view of a first surface of a first printed circuit board according to an embodiment of the disclosure.

Throughout the drawings, it should be noted that like reference numbers are used to depict the same or similar elements, features, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

It should be appreciated that the blocks in each flowchart and combinations of the flowcharts may be performed by one or more computer programs which include computer-executable instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g., a central processing unit (CPU)), a communication processor (CP, e.g., a modem), a graphical processing unit (GPU), a neural processing unit (NPU) (e.g., an artificial intelligence (AI) chip), a wireless-fidelity (Wi-Fi) chip, a Bluetooth™ chip, a global positioning system (GPS) chip, a near field communication (NFC) chip, connectivity chips, a sensor controller, a touch controller, a finger-print sensor controller, a display drive integrated circuit (IC), an audio CODEC chip, a universal serial bus (USB) controller, a camera controller, an image processing IC, a microprocessor unit (MPU), a system on chip (SoC), an IC, or the like.

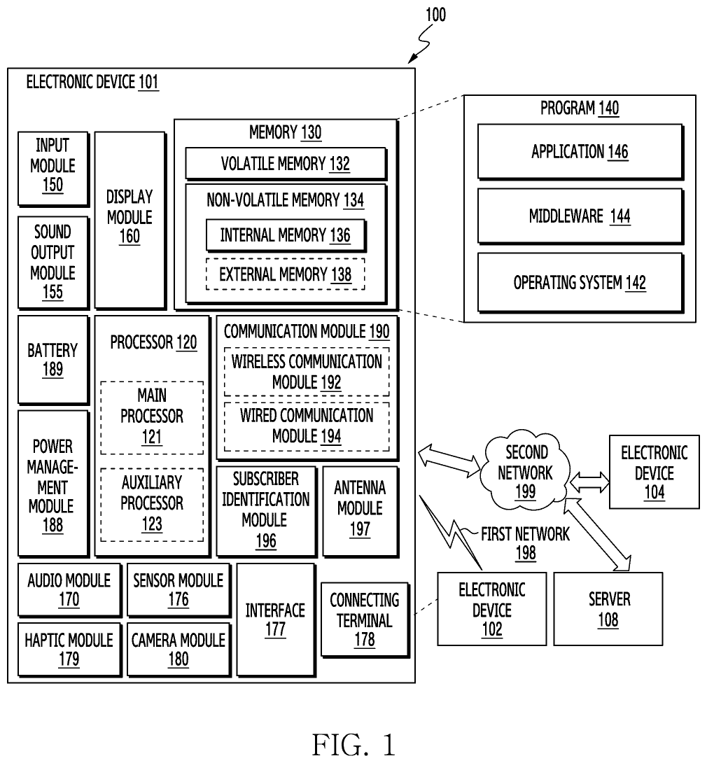

FIG. 1 is a block diagram illustrating an electronic device in a network environment according to an embodiment of the disclosure.

Referring to FIG. 1, an electronic device 101 in a network environment 100 may communicate with an external electronic device 102 via a first network 198 (e.g., a short-range wireless communication network), or at least one of an external electronic device 104 or a server 108 via a second network 199 (e.g., a long-range wireless communication network). According to an embodiment of the disclosure, the electronic device 101 may communicate with the external electronic device 104 via the server 108. According to an embodiment of the disclosure, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments of the disclosure, at least one of the components (e.g., the connecting terminal 178) may be omitted from the electronic device 101, or one or more other components may be added in the electronic device 101. In some embodiments of the disclosure, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment of the disclosure, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment of the disclosure, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., a sleep) state, or together with the main processor 121 while the main processor 121 is in an active state (e.g., executing an application). According to an embodiment of the disclosure, the auxiliary processor 123 (e.g., an image signal processor or a communication processor) may be implemented as part of another component (e.g., the camera module 180 or the communication module 190) functionally related to the auxiliary processor 123. According to an embodiment of the disclosure, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment of the disclosure, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment of the disclosure, the display module 160 may include a touch sensor adapted to detect a touch, or a pressure sensor adapted to measure the intensity of force incurred by the touch.

The audio module 170 may convert a sound into an electrical signal and vice versa. According to an embodiment of the disclosure, the audio module 170 may obtain the sound via the input module 150, or output the sound via the sound output module 155 or a headphone of an external electronic device (e.g., the external electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment of the disclosure, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the external electronic device 102) directly (e.g., wiredly) or wirelessly. According to an embodiment of the disclosure, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the external electronic device 102). According to an embodiment of the disclosure, the connecting terminal 178 may include, for example, an HDMI connector, a USB connector, an SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment of the disclosure, the haptic module 179 may include, for example, a motor, a piezoelectric element, or an electric stimulator.

The camera module 180 may capture a still image or moving images. According to an embodiment of the disclosure, the camera module 180 may include one or more lenses, image sensors, image signal processors, or flashes.

The power management module 188 may manage power supplied to the electronic device 101. According to an embodiment of the disclosure, the power management module 188 may be implemented as at least part of, for example, a power management integrated circuit (PMIC).

The battery 189 may supply power to at least one component of the electronic device 101. According to an embodiment of the disclosure, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the external electronic device 102, the external electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment of the disclosure, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a fifth generation (5G) network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a fourth generation (4G) network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the millimeter wave (mm Wave) band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the external electronic device 104), or a network system (e.g., the second network 199). According to an embodiment of the disclosure, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of Ims or less) for implementing URLLC.

The antenna module 197 may transmit or receive a signal or power to or from the outside (e.g., the external electronic device) of the electronic device 101. According to an embodiment of the disclosure, the antenna module 197 may include an antenna including a radiating element including a conductive material or a conductive pattern formed in or on a substrate (e.g., a printed circuit board (PCB)). According to an embodiment of the disclosure, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment of the disclosure, another component (e.g., a radio frequency integrated circuit (RFIC)) other than the radiating element may be additionally formed as part of the antenna module 197.

According to various embodiments of the disclosure, the antenna module 197 may form a mmWave antenna module. According to an embodiment of the disclosure, the mm Wave antenna module may include a printed circuit board, an RFIC disposed on a first surface (e.g., the bottom surface) of the printed circuit board, or adjacent to the first surface and capable of supporting a designated high-frequency band (e.g., the mm Wave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment of the disclosure, commands or data may be transmitted or received between the electronic device 101 and the external electronic device 104 via the server 108 coupled with the second network 199. Each of the external electronic devices 102 or 104 may be a device of a same type as, or a different type, from the electronic device 101. According to an embodiment of the disclosure, all or some of operations to be executed at the electronic device 101 may be executed at one or more of the external electronic devices 102 or 104, or the server 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment of the disclosure, the external electronic device 104 may include an Internet-of-things (IoT) device. The server 108 may be an intelligent server using machine learning and/or a neural network. According to an embodiment of the disclosure, the external electronic device 104 or the server 108 may be included in the second network 199. The electronic device 101 may be applied to intelligent services (e.g., a smart home, a smart city, embodiment of the disclosure smart car, or healthcare) based on 5G communication technology or IoT-related technology.

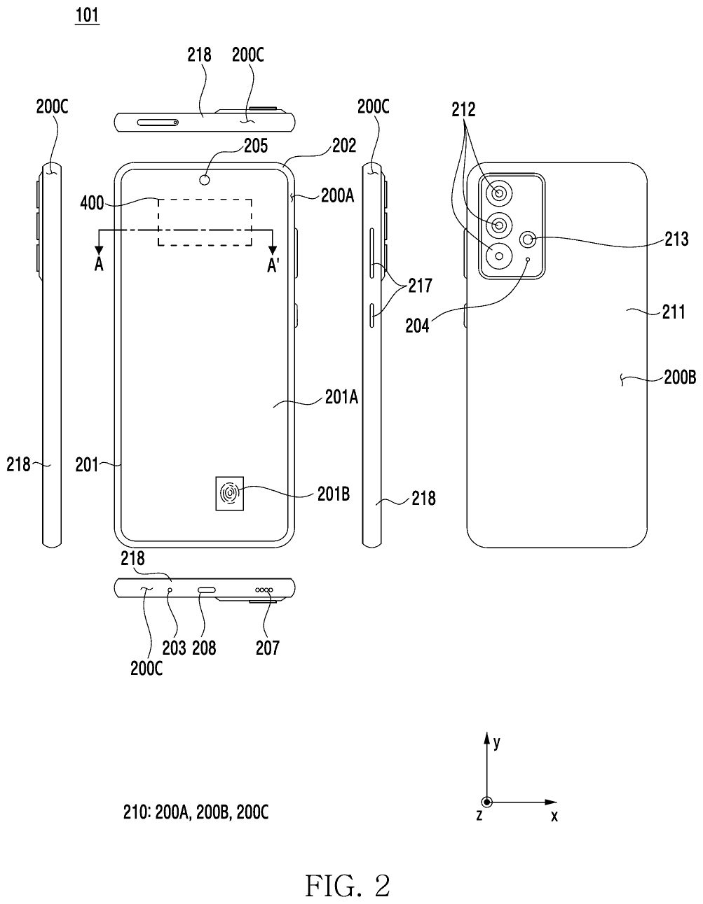

FIG. 2 illustrates an electronic device according to an embodiment of the disclosure.

Referring to FIG. 2, an electronic device 101 according to an embodiment of the disclosure may include a housing 210 forming an exterior of the electronic device 101. For example, the housing 210 may include a first surface (or a front surface) 200A, a second surface (or a rear surface) 200B, and a third surface (or a side surface) 200C surrounding a space between the first surface 200A and the second surface 200B.

The electronic device 101 according to an embodiment of the disclosure may include a substantially transparent first plate 202. According to an embodiment of the disclosure, the first plate 202 may form at least a portion of the first surface 200A. According to an embodiment of the disclosure, the first plate 202 may include, for example, a glass plate including various coating layers, or a polymer plate, but is not limited thereto.

The electronic device 101 according to an embodiment of the disclosure may include a substantially opaque second plate 211. According to an embodiment of the disclosure, the second plate 211 may form at least a portion of the second surface 200B. According to an embodiment of the disclosure, the second plate 211 may be formed by a coated or colored glass, ceramic, polymer, metal (e.g., aluminum, stainless steel (STS), or magnesium), or a combination of at least two of the materials.

The electronic device 101 according to an embodiment of the disclosure may include a side frame 218. According to an embodiment of the disclosure, the side frame 218 may form at least a portion of the third surface 200C of the electronic device 101 by being coupled with the first plate 202 and/or the second plate 211. For example, the side frame 218 may also entirely form the third surface 200C of the electronic device 101. For example, the side frame 218 may also form the third surface 200C of the electronic device 101 together with the first plate 202 and/or the second plate 211.

The electronic device 101 according to an embodiment of the disclosure may include at least one of a display 201, audio modules 203, 204, and 207, a sensor module (not illustrated), camera modules 205, 212, and 213, a key input device 217, a light-emitting element (not illustrated), and/or a connector hole 208. According to an embodiment of the disclosure, the electronic device 101 may omit at least one of the components (e.g., the key input device 217 or the light-emitting element (not illustrated)), or may additionally include another component.

According to an embodiment of the disclosure, at least a portion of the display 201 (e.g., the display module 160 of FIG. 1) may be visible through the first plate 202 forming the first surface 200A. According to an embodiment of the disclosure, the display 201 may be disposed on a rear surface of the first plate 202.

According to an embodiment of the disclosure, a shape of an outer periphery of the display 201 may be formed substantially the same as a shape of an outer periphery of the first plate 202 adjacent to the display 201. According to an embodiment of the disclosure, in order to expand an area to which the display 201 is visually exposed, a gap between the outer periphery of the display 201 and the outer periphery of the first plate 202 may be formed substantially the same.

According to an embodiment of the disclosure, the display 201 (or the first surface 200A of the electronic device 101) may include a screen display region 201A. According to an embodiment of the disclosure, the display 201 may provide a user with visual information through the screen display region 201A. In the illustrated embodiment of the disclosure, when the first surface 200A is viewed from the front, the screen display region 201A is illustrated as being spaced apart from an outer periphery of the first surface 200A and being positioned inside the first surface 200A, but it is not limited thereto. According to an embodiment of the disclosure, when the first surface 200A is viewed from the front, at least a portion of a periphery of the screen display region 201A may be substantially coincided with a periphery of the first surface 200A (or the first plate 202).

According to an embodiment of the disclosure, the screen display region 201A may include a sensing region 201B configured to obtain biometric information of the user. Herein, a meaning of “the screen display region 201A includes the sensing region 201B” may be understood as that at least a portion of the sensing region 201B may be overlapped with the screen display region 201A. For example, the sensing region 201B may mean a region that may display the visual information by the display 201 similar to another region of the screen display region 201A, and that may additionally obtain the biometric information (e.g., a fingerprint) of the user. According to an embodiment of the disclosure, the sensing region 201B may also be formed in the key input device 217.

According to an embodiment of the disclosure, the display 201 may include a region in which the first camera module 205 (e.g., the camera module 180 of FIG. 1) is positioned. According to an embodiment of the disclosure, an opening is formed in the region of the display 201, and the first camera module 205 (e.g., a punch hole camera) may be at least partially disposed in the opening to face the first surface 200A. In this case, the screen display region 201A may surround at least a portion of a periphery of the opening. According to an embodiment of the disclosure, the first camera module 205 (e.g., an under display camera (UDC)) may be disposed under the display 201 to overlap the region of the display 201. In this case, the display 201 may provide the user with the visual information through the region, and additionally, the first camera module 205 may obtain an image corresponding to a direction facing the first surface 200A through the region of the display 201.

According to an embodiment of the disclosure, the display 201 may be coupled with or disposed adjacent to touch sensing circuitry, a pressure sensor capable of measuring intensity (pressure) of a touch, and/or a digitizer that detects a magnetic field type stylus pen.

According to an embodiment of the disclosure, the audio modules 203, 204, and 207 (e.g., the audio module 170 of FIG. 1) may include the microphone holes 203 and 204 and/or the speaker hole 207.

According to an embodiment of the disclosure, the microphone holes 203 and 204 may include the first microphone hole 203 formed in a partial region of the third surface 200C and/or the second microphone hole 204 formed in a partial region of the second surface 200B. A microphone (not illustrated) for obtaining an external sound may be disposed inside the microphone holes 203 and 204. The microphone may include a plurality of microphones to sense a direction of sound.

According to an embodiment of the disclosure, the second microphone hole 204 formed in the partial region of the second surface 200B may be disposed to be adjacent to the camera modules 212 and 213. For example, the second microphone hole 204 may obtain sound according to an operation of the camera modules 212 and 213. However, it is not limited thereto.

According to an embodiment of the disclosure, the speaker hole 207 may include an external speaker hole 207 and a call receiver hole (not illustrated). The external speaker hole 207 may be formed in a portion of the third surface 200C of the electronic device 101. According to an embodiment of the disclosure, the external speaker hole 207 may be implemented as one hole with the microphone hole 203. Although not illustrated, the call receiver hole (not illustrated) may be formed on another portion of the third surface 200C. For example, the call receiver hole may be formed on an opposite side of the external speaker hole 207 on the third surface 200C. For example, based on the illustration of FIG. 2, the external speaker hole 207 may be formed on the third surface 200C corresponding to a lower end of the electronic device 101, and the call receiver hole may be formed on the third surface 200C corresponding to an upper end of the electronic device 101. However, it is not limited thereto, and according to an embodiment of the disclosure, the call receiver hole may be formed at a position other than the third surface 200C. For example, the call receiver hole may be formed by a space separated between the first plate 202 (or the display 201) and the side frame 218.

According to an embodiment of the disclosure, the electronic device 101 may include at least one speaker (not illustrated) configured to output sound to the outside of the housing 210 through the external speaker hole 207 and/or the call receiver hole (not illustrated).

According to an embodiment of the disclosure, the sensor module (not illustrated) (e.g., the sensor module 176 of FIG. 1) may generate an electrical signal or a data value corresponding to an operating state inside the electronic device 101 or an external environmental state. For example, the sensor module may include at least one of a proximity sensor, a heart rate monitor (HRM) sensor, a fingerprint sensor, a gesture sensor, a gyro sensor, a barometric sensor, a magnetic sensor, an acceleration sensor, a grip sensor, a color sensor, an infrared (IR) sensor, a biometric sensor, a temperature sensor, a humidity sensor, or an illuminance sensor.

According to an embodiment of the disclosure, the camera modules 205, 212, and 213 (e.g., the camera module 180 of FIG. 1) may include the first camera module 205 disposed to face the first surface 200A of the electronic device 101, the second camera module 212 disposed to face the second surface 200B, and the flash 213.

According to an embodiment of the disclosure, the second camera module 212 may include a plurality of cameras (e.g., a dual camera, a triple camera, or a quad camera). However, the second camera module 212 is not necessarily limited to including the plurality of cameras, and may also include one camera.

According to an embodiment of the disclosure, the first camera module 205 and the second camera module 212 may include one or more lenses, an image sensor, and/or an image signal processor.

According to an embodiment of the disclosure, the flash 213 may include, for example, a light-emitting diode or a xenon lamp. According to an embodiment of the disclosure, two or more lenses (an infrared camera and a wide-angle and telephoto lens) and image sensors may be disposed on one surface of the electronic device 101.

According to an embodiment of the disclosure, the key input device 217 (e.g., the input module 150 of FIG. 1) may be disposed on the third surface 200C of the electronic device 101. According to an embodiment of the disclosure, the electronic device 101 may not include some or all of the key input device 217, and the key input device 217 that is not included may be implemented in another form, such as a soft key, on the display 201.

According to an embodiment of the disclosure, the connector hole 208 may be formed on the third surface 200C of the electronic device 101 such that a connector of an external device may be accommodated. A connection terminal (e.g., the connection terminal 178 of FIG. 1) electrically connected with the connector of the external device may be disposed in the connector hole 208. The electronic device 101 according to an embodiment of the disclosure may include an interface module (e.g., the interface 177 of FIG. 1) for processing an electrical signal transmitted and received through the connection terminal.

According to an embodiment of the disclosure, the electronic device 101 may include the light-emitting element (not illustrated). For example, the light-emitting element (not illustrated) may be disposed on the first surface 200A of the housing 210. The light-emitting element (not illustrated) may provide state information of the electronic device 101 in a form of light. According to an embodiment of the disclosure, the light-emitting element (not illustrated) may provide a light source linked with an operation of the first camera module 205. For example, the light-emitting element (not illustrated) may include an LED, an IR LED, and/or the xenon lamp.

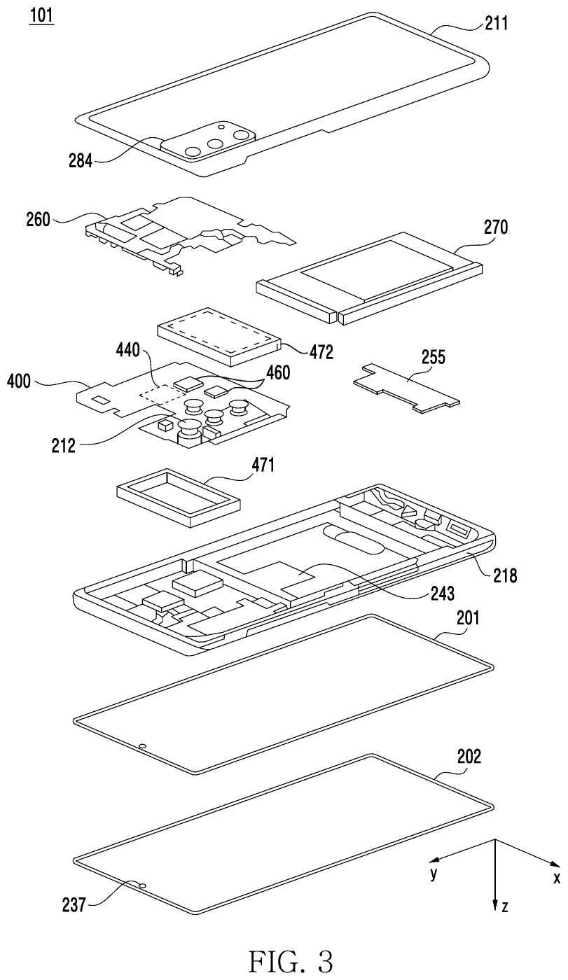

FIG. 3 is an exploded perspective view of an electronic device according to an embodiment of the disclosure.

Hereinafter, an overlapping description of a configuration having the same reference numerals as the above-described configuration will be omitted.

Referring to FIG. 3, an electronic device 101 according to an embodiment of the disclosure may include a display 201, a first plate 202, a second plate 211, a side frame 218, a supporting member 243, a printed circuit board 400, a sub-PCB 255, a cover plate 260, a battery 270, and/or a shield can 320.

The electronic device 101 according to an embodiment of the disclosure may include the side frame 218 forming an exterior (e.g., the third surface 200C of FIG. 2) of the electronic device 101 and the supporting member 243 extending inward from the side frame 218. According to an embodiment of the disclosure, the side frame 218 and the supporting member 243 may be disposed between the display 201 and the second plate 211. For example, the side frame 218 may surround a space between the second plate 211 and the first plate 202 (and/or the display 201). For example, the supporting member 243 may extend from the side frame 218 in the space.

According to an embodiment of the disclosure, the supporting member 243 may support or accommodate other components included in the electronic device 101. For example, the display 201 may be disposed on a surface of the supporting member 243 facing a direction (e.g., a +z direction), and the display 201 may be supported by the supporting member 243. For example, the PCB 400, the battery 270, and a second camera module 212 may be disposed on another surface facing a direction (e.g., a −z direction) opposite to the direction of the supporting member 243. For example, the PCB 400, the battery 270, and the second camera module 212 may each be seated in a recess defined by the side frame 218 and/or the supporting member 243.

According to an embodiment of the disclosure, the PCB 400 and the battery 270 may be coupled with the supporting member 243, respectively. For example, the PCB 400 may be fixedly disposed on the supporting member 243 through a coupling member, such as a screw. For example, the battery 270 may be fixedly disposed on the supporting member 243 through an adhesive member (e.g., a double-sided tape). However, it is not limited by the above-described example.

According to an embodiment of the disclosure, the cover plate 260 may be disposed between the PCB 400 and the second plate 211. According to an embodiment of the disclosure, the cover plate 260 may be disposed on the PCB 400. For example, the cover plate 260 may be disposed on a surface of the PCB 400 facing the −z direction.

According to an embodiment of the disclosure, the cover plate 260 may at least partially overlap the PCB 400 with respect to a z-axis. According to an embodiment of the disclosure, the cover plate 260 may cover at least a partial region of the PCB 400. In this way, the cover plate 260 may protect the PCB 400 from a physical impact or prevent detachment of a connector coupled to the PCB 400.

According to an embodiment of the disclosure, the cover plate 260 may be fixedly disposed on the PCB 400 through the coupling member (e.g., the screw), or may be coupled to the supporting member 243 together with the PCB 400 through the coupling member.

According to an embodiment of the disclosure, the display 201 may be disposed between the supporting member 243 and the first plate 202. For example, the first plate 202 may be disposed in a side (e.g., in the +z direction) of the display 201, and the supporting member 243 may be disposed in another side (e.g., in the −z direction).

According to an embodiment of the disclosure, the first plate 202 may be coupled with the display 201. For example, the first plate 202 and the display 201 may be attached to each other through an optical adhesive member (e.g., an optically clear adhesive (OCA) or an optically clear resin (OCR)) interposed therebetween.

According to an embodiment of the disclosure, the first plate 202 may be coupled with the side frame 218. For example, the first plate 202 may include an outer portion extending outside the display 201 when viewed in a z-axis direction, and may be attached with the side frame 218 through an adhesive member (e.g., a waterproof tape) disposed between the outer portion of the first plate 202 and the side frame 218. However, it is not limited by the above-described example.

According to an embodiment of the disclosure, a processor (e.g., the processor 120 of FIG. 1), memory (e.g., the memory 130 of FIG. 1), and/or an interface (e.g., the interface 177 of FIG. 1) may be disposed on the PCB 400. The processor may include, for example, one or more of a central processing unit, an application processor, a graphic processing unit, an image signal processor, a sensor hub processor, or a communication processor. The memory may include, for example, volatile memory or non-volatile memory. The interface may include, for example, a high definition multimedia interface (HDMI), a universal serial bus (USB) interface, an SD card interface, and/or an audio interface. The interface may electrically or physically connect the electronic device 101 to an external electronic device, and may include a USB connector, an SD card/MMC connector, or an audio connector. According to an embodiment of the disclosure, the electronic device 101 may include the sub-PCB 255. The PCB 400 and the sub-PCB 255 may be operatively or electrically connected to each other through a connection member (e.g., a flexible PCB).

According to an embodiment of the disclosure, the battery 270 (e.g., the battery 189 of FIG. 1) may supply power to at least one component of the electronic device 101. For example, the battery 270 may include a rechargeable secondary battery or a fuel cell. At least a portion of the battery 270 may be disposed on substantially the same plane as the PCB 400 and/or the sub-PCB 255.

The electronic device 101 according to an embodiment of the disclosure may include an antenna module (not illustrated) (e.g., the antenna module 197 of FIG. 1). According to an embodiment of the disclosure, the antenna module may be disposed between the second plate 211 and the battery 270. The antenna module may include, for example, a near field communication (NFC) antenna, a wireless charging antenna, and/or a magnetic secure transmission (MST) antenna. The antenna module may, for example, perform short-range communication with an external device or wirelessly transmit and receive power to and from the external device.

According to an embodiment of the disclosure, a first camera module 205 (e.g., a front camera) may be disposed in at least a portion of the supporting member 243 such that a lens may receive external light through a partial region (e.g., a camera region 237) of the first plate 202 (e.g., the front surface 200A of FIG. 2).

According to an embodiment of the disclosure, the second camera module 212 (e.g., a rear camera) may be disposed between the supporting member 243 and the second plate 211. According to an embodiment of the disclosure, the second camera module 212 may be electrically connected to the PCB 400 through a connection member (e.g., the connector). According to an embodiment of the disclosure, the second camera module 212 may be disposed such that a lens may receive external light through a camera region 284 of the second plate 211 of the electronic device 101.

According to an embodiment of the disclosure, the camera region 284 may be formed on a surface (e.g., the rear surface 200B of FIG. 2) of the second plate 211. According to an embodiment of the disclosure, the camera region 284 may be formed to be at least partially transparent such that the external light may be incident on the lens of the second camera module 212. According to an embodiment of the disclosure, at least a portion of the camera region 284 may protrude from the surface of the second plate 211 to a predetermined height. However, it is not limited thereto, and according to an embodiment of the disclosure, the camera region 284 may also form substantially the same plane as the surface of the second plate 211.

According to an embodiment of the disclosure, a housing 210 of the electronic device 101 may mean a configuration or a structure forming at least a portion of the exterior of the electronic device 101. In this respect, at least a portion of the first plate 202, the side frame 218, and/or the second plate 211 forming the exterior of the electronic device 101 may be referred to as the housing 210 of the electronic device 101.

According to an embodiment of the disclosure, the PCB 400 may provide an electrical connection between electronic components of the electronic device 101. For example, the PCB 400 may include a plurality of conductive layers and a plurality of non-conductive layers alternately stacked with the plurality of conductive layers. For example, the PCB 400 may provide the electrical connection for the electronic components using wirings and conductive vias formed on the conductive layer.

The electronic device 101 according to an embodiment of the disclosure may include electronic components for implementing various functions of the electronic device 101. For example, the electronic device 101 may include a first electronic component 440 and a third electronic component 460 disposed on the PCB 400.

According to an embodiment of the disclosure, the PCB 400 may be a stacked type substrate. The PCB 400 may include a first PCB 410, a second PCB 420, and an interposer 430. A second electronic component 450 may be positioned in an inner space formed by the first PCB 410, the second PCB 420, and the interposer 430. For example, the first electronic component 440 may be exposed to the outside of the PCB 400, and the second electronic component 450 may be positioned inside the PCB 400. The first electronic component 440 may be disposed on a surface of the PCB 400 facing the display 201. The third electronic component 460 may be disposed on a surface of the PCB 400 facing the second plate 211. The electronic device 101 may include a first shield can 471 to cover the first electronic component 440 and a second shield can 472 to cover the third electronic component 460. The PCB 400 may be referred to as a PCB assembly.

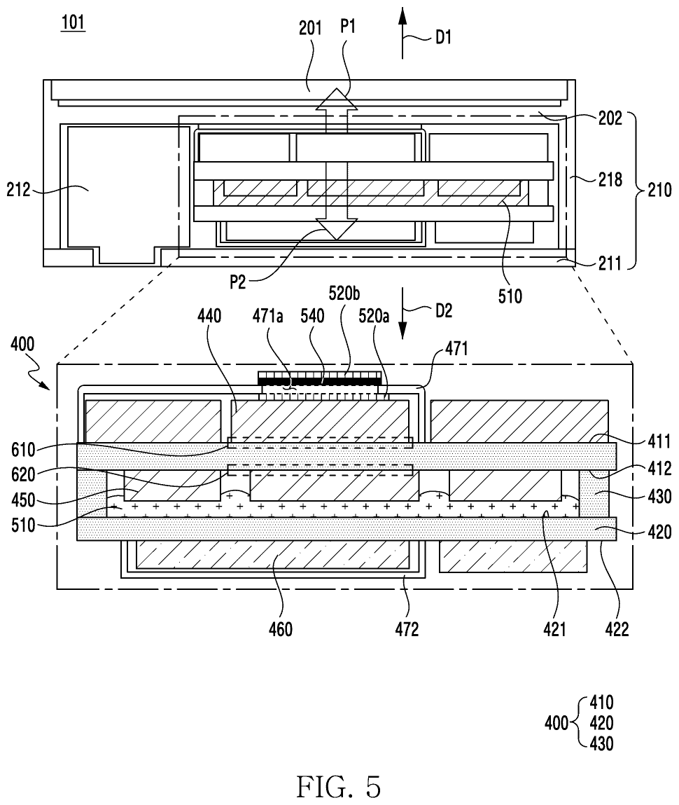

The electronic device 101 according to an embodiment of the disclosure may include a thermal interface material (TIM) (e.g., a thermal interface material 510 of FIG. 5). For example, the TIM 510 may comprise a polymer composite material, a thermally conductive filler, and a dispersant. A thermally conductive material may suppress an increase in an internal temperature of the electronic device 101 by diffusing heat. As the number of electronic components integrated on the PCB 400 is increased in order to implement various functions of the electronic device 101, more heat may be generated. For example, heat generated from the first electronic component 440 disposed toward the display 201 may be conducted toward the display 201. Due to the heat, a temperature increase of the first electronic component 440 may be caused, and the first electronic component 440 may limit a performance of the display 201 to reduce damage due to the temperature increase. For example, the first electronic component 440 may reduce heat generation by lowering a clock and a voltage through throttling. According to an embodiment of the disclosure, as the TIM 510 is included in an inner space (or an internal volume) of the stacked type substrate, a portion of the heat generated from the first electronic component 440 may be conducted toward the second plate 211. As the heat generated from the first electronic component 440 is conducted in different directions, the temperature increase of the electronic device 101 may be reduced, and performance deterioration of the display 201 may be reduced. The electronic device 101 according to an embodiment of the disclosure may have a structure for effectively transferring the heat generated from the first electronic component 440 toward the second plate 211. Hereinafter, the electronic device 101 according to an embodiment will be described.

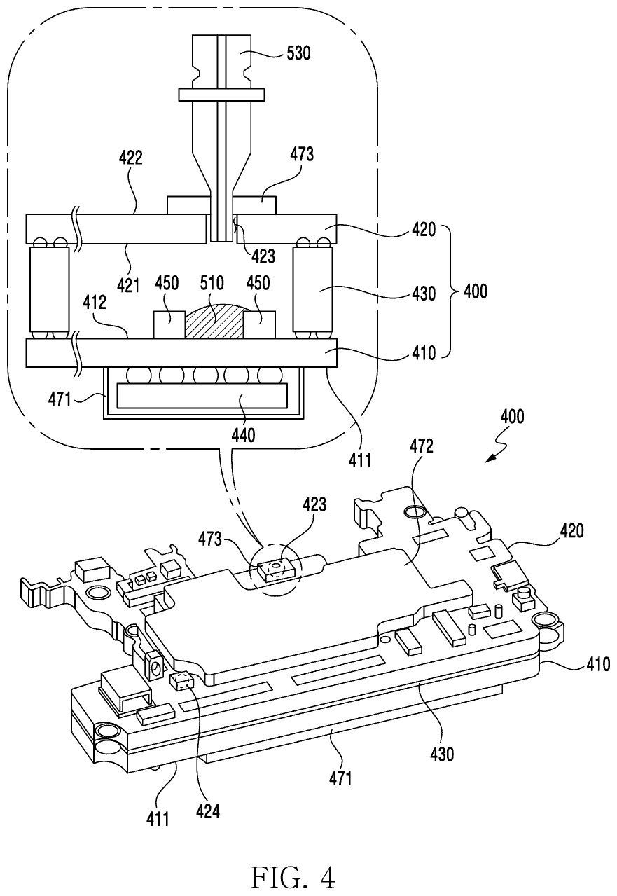

FIG. 4 illustrates a printed circuit board according to an embodiment of the disclosure.

Referring to FIG. 4, a PCB 400 according to an embodiment of the disclosure may be referred to as a stacked type board on which a plurality of PCBs 410 and 420 are stacked. For example, the PCB 400 may be referred to as a circuit board assembly on which the plurality of PCBs 410 and 420 are stacked.

According to an embodiment of the disclosure, the PCB 400 may include a first PCB 410, a second PCB 420, and an interposer 430.

According to an embodiment of the disclosure, the second PCB 420 may be spaced apart from the first PCB 410. For example, a gap between the first PCB 410 and the second PCB 420 may be approximately 0.65 mm, but is not limited thereto. The interposer 430 may be disposed between the first PCB 410 and the second PCB 420. For example, the interposer 430 may be disposed along a periphery between the first PCB 410 and the second PCB 420. The interposer 430 may be connected between the first PCB 410 and the second PCB 420. The interposer 430 may provide an electrical connection between the first PCB 410 and the second PCB 420. The interposer 430 may provide an electromagnetic shielding function for electronic components disposed between the first PCB 410 and the second PCB 420. For example, the interposer 430 may shield electromagnetic noise transmitted to the electronic components disposed between the first PCB 410 and the second PCB 420 by including a conductive material to shield an electromagnetic wave emitted from other electronic components of an electronic device 101. A space covered by the first PCB 410, the second PCB 420, and the interposer 430 may be formed (or defined). The space may be referred to as an inner space of the PCB 400 or an internal volume of the PCB 400. The PCB 400 having a structure on which the first PCB 410 and the second PCB 420 are stacked may have a high degree of integration since various electronic components may be disposed.

According to an embodiment of the disclosure, a first electronic component 440 and a first shield can 471 may be disposed on the first PCB 410. For example, a first electronic component (e.g., a first electronic component 440 of FIG. 5) may include an application processor (AP) for controlling an overall operation of the electronic device 101, but is not limited thereto. For example, the first electronic component 440 may be disposed on a first surface 411 of the first PCB 410. For example, the first electronic component 440, which is circuitry that performs processing, may include an application processor (AP, e.g., a central processing unit (CPU)), a communication processor (CP, e.g., a modem), a graphic processing unit (e.g., a GPU), a neural processing unit (e.g., an artificial intelligence (AI) chip), a wireless-fidelity (Wi-Fi) chip, a Bluetooth™ chip, a global positioning system (GPS) chip, a near field communication (NFC) chip, connectivity chips, a sensor controller, a touch controller, a finger-print sensor controller, a display drive integrated (DDI) circuit, an audio CODEC chip, a universal serial bus (USB) controller, a camera controller, an image processing IC, a microprocessor unit (MPU), a system on a chip (SoC), an IC, or similar circuitry. However, the above-described examples are merely exemplary, and the first electronic component 440 is not limited thereto.

According to an embodiment of the disclosure, a second electronic component (e.g., a second electronic component 450 of FIG. 5) may be positioned in a space formed by the first PCB 410, the second PCB 420, and the interposer 430. For example, a second electronic component 450 may be disposed on a second surface (e.g., a second surface 412 of FIG. 5) of the first PCB 410. For example, the second electronic component 450 may be plural. The second electronic component 450 may include a power-related IC (e.g., a power management integrated circuit (PMIC)) and/or passive elements (e.g., a resistor, an inductor, and a capacitor).

According to an embodiment of the disclosure, a thermal interface material 510 may be included in the space. As the TIM 510 fills at least a portion of the space, heat generated from the first electronic component 440 and/or the second electronic component 450 may be diffused through the TIM 510. The TIM 510 may be injected into the space after the PCB 400 is manufactured.

According to an embodiment of the disclosure, the second PCB 420 may include (or define) a first opening 423 into which a nozzle 530 for insertion of the TIM 510 may be injected. The first opening 423 may be referred to as an injection hole in terms of being used as an opening for insertion of the nozzle 530. The first opening 423 may be at least partially covered by a sealing member 473. The sealing member 473 may include a cutout portion for insertion of the nozzle 530. The nozzle 530 may be inserted into the first opening 423 while pushing the cutout portion. A diameter of the first opening 423 may be approximately 1.3 mm, but is not limited thereto. The first opening 423 may be referred to as a first through hole.

According to an embodiment of the disclosure, the second PCB 420 may include (or define) a second opening 424 for inspecting an injection state of the TIM 510. The second opening 424 may be referred to as an observation hole in terms of being used as an opening for inspecting the injection state of the TIM 510. The second opening 424 may be used to inspect the injection state, such as an injection amount and an injection position of the TIM 510. The second opening 424 may be referred to as a second through hole.

According to an embodiment of the disclosure, a third electronic component (e.g., a third electronic component 460 of FIG. 5) and a second shield can 472 may be disposed on the second PCB 420. For example, the third electronic component 460 may include a radio frequency (RF) module (e.g., an RF transceiver). The second shield can 472 may shield an electromagnetic wave generated when the third electronic component 460 operates, by covering the third electronic component 460. For example, the third electronic component 460 may be covered such that an electromagnetic wave emitted from the third electronic component 460 does not affect another electronic component, or that an electromagnetic wave emitted from the other electronic component does not affect the third electronic component 460. As the third electronic component 460 is covered by the second shield can 472, interference by the electromagnetic wave may be reduced.

According to an embodiment of the disclosure, the first opening 423 and the second opening 424 may be formed to avoid the second shield can 472. In a case that the first opening 423 is formed at a position overlapping the second shield can 472, the nozzle 530 may not be inserted by the second shield can 472. For the insertion of the nozzle 530, the first opening 423 may be spaced apart from the second shield can 472. In a case that the second opening 424 is formed at a position overlapping the second shield can 472, inspection of the injection state of the TIM 510 may be impossible by the second shield can 472. In order to inspect an injection state of the TIM 510, the second opening 424 may be spaced apart from the second shield can 472.

Hereinafter, a structure for injecting a sufficient amount of the TIM 510 into the inner space of the PCB 400 will be described with reference to an internal structure of the PCB 400 and a structure of a housing 210 of an electronic device (e.g., the electronic device 101 of FIG. 2).

FIG. 5 is a cross-sectional view in which an electronic device is cut along line A-A′ of FIG. 2 according to an embodiment of the disclosure.

Referring to FIG. 5, an electronic device 101 may include a display 201 and a housing 210.

According to an embodiment of the disclosure, the display 201 may be configured to display visual information. The display 201 may display the visual information by controlling pixels, and may form at least a portion of a front surface of the electronic device 101 such that the displayed visual information may be transmitted to a user. For example, the portion of the front surface of the electronic device 101 may be formed by the display 201. The display 201 may be disposed to face the outside of the electronic device 101. In the disclosure, a direction to which the display 201 faces may be referred to as a first direction D1. In the disclosure, a second direction D2 may be referred to as a direction opposite to the first direction D1.

According to an embodiment of the disclosure, the housing 210 may form at least a portion of an exterior of the electronic device 101. For example, the housing 210 may include a first plate 202, a second plate 211, and a frame 218. At least a portion of the first plate 202 may support the display 201. The first plate 202 may face the first direction D1. The first plate 202 facing the first direction D1 may be referred to as a direction in which an outer surface of the first plate 202 faces substantially corresponds to the first direction D1. The first plate 202 may be referred to as a front plate or a front cover in terms of forming a front surface of the housing 210. The second plate 211 may form at least a portion of a rear surface of the electronic device 101. For example, at least a portion of the second plate 211 may be opposite to the display 201 forming the at least a portion of the front surface of the electronic device 101. The second plate 211 may face the second direction D2. The second plate 211 facing the second direction D2 may be referred to as a direction in which an outer surface of the second plate 211 faces substantially corresponds to the second direction D2. The second plate 211 may be referred to as a rear plate or a rear cover in terms of forming a rear surface of the housing 210. The frame 218 may form an inner space of the housing 210 by being disposed between the first plate 202 and the second plate 211.

According to an embodiment of the disclosure, components of the electronic device 101 may be disposed inside the housing 210. For example, a camera module 212, a printed circuit board 400, a first electronic component 440, a second electronic component 450, and/or a third electronic component 460 may be disposed inside the housing 210.

According to an embodiment of the disclosure, the PCB 400, which is a stacked type board, may include a first PCB 410, a second PCB 420, and an interposer 430. According to an embodiment of the disclosure, the first PCB 410 may include a first surface 411 and a second surface 412. For example, the first surface 411 may be a surface of the first PCB 410 facing the first direction D1. For example, the second surface 412 may be a surface of the first PCB 410 facing the second direction D2. The second surface 412 may be opposite to the first surface 411. The first electronic component 440 may be electrically connected with the first PCB 410 by being disposed on the first surface 411. For example, a region on the first surface 411 on which the first electronic component 440 is disposed may be referred to as a first portion 610. A second portion 620 may be referred to as a region of the second surface 412 facing the first portion 610.

The second electronic component 450 may be electrically connected with the first PCB 410 by being disposed on the second surface 412. The second electronic component 450 may be positioned in a space between the first PCB 410 and the second PCB 420. For example, the first electronic component 440 may include an AP, but is not limited thereto. For example, the second electronic component 450 may include a passive element, but is not limited thereto.

According to an embodiment of the disclosure, the second PCB 420 may be spaced apart from the first PCB 410 in the second direction D2. For example, a distance between the first PCB 410 and the second PCB 420 may be approximately 0.6 mm, but is not limited thereto. The second PCB 420 may be electrically connected with the first PCB 410 through the interposer 430.

According to an embodiment of the disclosure, the second PCB 420 may include a third surface 421 and a fourth surface 422. For example, the third surface 421 may be a surface of the second PCB 420 facing the first direction D1. For example, the fourth surface 422 may be a surface of the second PCB 420 facing the second direction D2. The fourth surface 422 may be opposite to the third surface 421. The third electronic component 460 may be electrically connected with the second PCB 420 by being disposed on the fourth surface 422. For example, the third electronic component 460 may include an RF module, but is not limited thereto.

According to an embodiment of the disclosure, a first shield can 471 may be disposed on the first surface 411 of the first PCB 410. The first shield can 471 may cover at least a portion of the first electronic component 440 disposed on the first surface 411. According to an embodiment of the disclosure, the first shield can 471 may include a third opening 471a facing the AP. For example, when the first shield can 471 is viewed from above, the third opening 471a and the AP may at least partially overlap. The third opening 471a may provide a path (e.g., a first thermal transfer path P1) through which heat generated from the AP is discharged to the outside of the first shield can 471. The AP may include a central processing unit (CPU) and/or a graphic processing unit (GPU). Since a transistor integrated inside the CPU and/or the GPU performs various calculations, the AP may generate relatively more heat. In a case that the first shield can 471 does not include the third opening 471a, the heat generated from the AP may not be discharged to the outside of the first shield can 471 and may remain inside the first shield can 471. In case that the heat remains inside the first shield can 471, a temperature increase of the AP may be caused. The third opening 471a may provide the first thermal transfer path P1 such that the heat generated from the AP may be substantially transferred through the first direction D1. Another TIM 520a may be disposed on an upper surface of the AP such that the heat generated from the AP may be transferred. In order to block an electromagnetic wave, a shielding sheet 540 covering the opening 471a may be disposed. A TIM 520b may be additionally disposed between the shielding sheet 540 and the first plate 202.

In a case that heat generated from the first electronic component 440 (e.g., the AP) is transferred along the first thermal transfer path P1 toward the first direction D1, a temperature increase of the display 201 positioned in the first direction D1 with respect to the first electronic component 440 may be caused. In order to reduce damage due to a temperature increase, a clock of the GPU may be decreased. For example, in a case that the temperature of the display 201 exceeds a threshold temperature, the clock of the GPU may be decreased, thereby deteriorating a quality of the visual information displayed on the display 201.

According to an embodiment of the disclosure, as the TIM 510 is included in the space between the first PCB 410 and the second PCB 420, a second thermal transfer path P2 through which the heat generated from the first electronic component 440 (e.g., the AP) is transferred in the second direction D2 may be formed. For example, since the first electronic component 440 is in contact with the first PCB 410, the heat generated from the first electronic component 440 may be transferred to the first PCB 410. As the TIM 510 included in the space is in contact with the first PCB 410, the heat may be transferred in the second direction D2 by the TIM 510. According to an embodiment of the disclosure, the TIM 510 may form the second thermal transfer path P2 through which the heat generated from the first electronic component 440 is transferred in the second direction D2. According to an embodiment of the disclosure, since the heat generated from the first electronic component 440 may be diffused along the first thermal transfer path P1 and the second thermal transfer path P2, the heat may be relatively evenly diffused without being concentrated in a specific region. According to an embodiment of the disclosure, a heat dissipation effect of the first electronic component 440 may be enhanced, and performance deterioration of the display 201 may be reduced. For example, when the first electronic component 440 operates, as a time for the temperature of the display 201 to reach the threshold temperature is delayed, the performance of the display 201 may be improved.

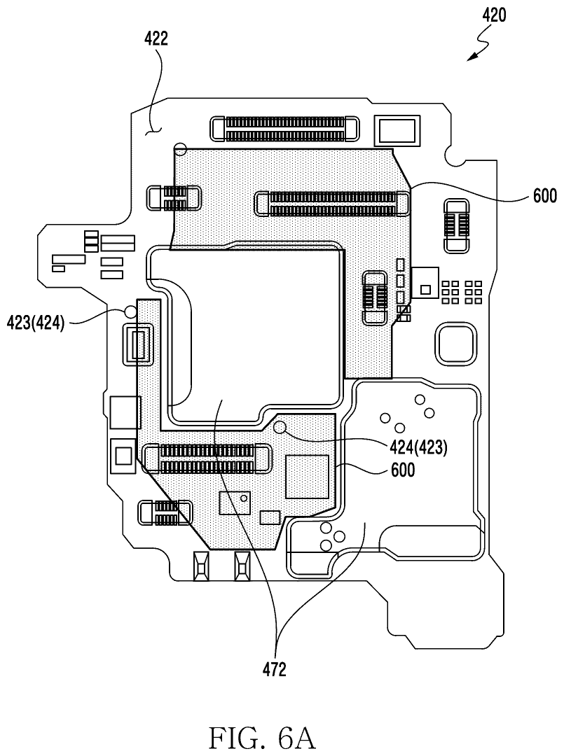

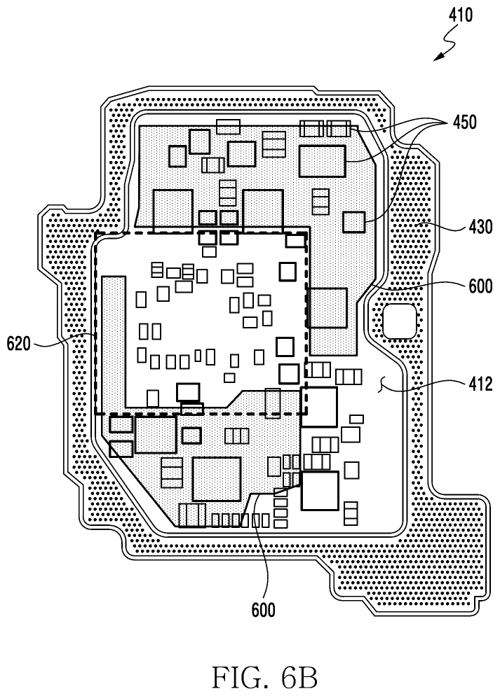

FIG. 6A is a front view of a fourth surface of a second printed circuit board according to an embodiment of the disclosure. FIG. 6B is a front view of a second surface of a first printed circuit board according to an embodiment of the disclosure.

FIG. 6A is a diagram of a fourth surface 422 of a second PCB 420 viewed from above. FIG. 6B is a diagram of a second surface 412 of a first PCB 410 viewed from above.

Referring to FIGS. 6A and 6B, the second PCB 420 may include a first opening 423 and a second opening 424. As described above, the first opening 423 may be an opening into which a nozzle (e.g., the nozzle 530 of FIG. 4) is inserted. A nozzle 530 for injecting a thermal interface material (e.g., the TIM 510 of FIG. 4) into a space between the first PCB 410 and the second PCB 420 may be inserted through the first opening 423. As the TIM 510 is discharged from the nozzle 530, at least a portion of the space may be filled by the TIM 510, in a state that the nozzle 530 is inserted. The second opening 424 may be an opening for inspecting an injection state of the TIM 510.

According to an embodiment of the disclosure, a second shield can 472 may be disposed on the fourth surface 422. The second shield can 472 may cover a third electronic component 460. The first opening 423 and the second opening 424 may be formed by avoiding the second shield can 472 so as not to overlap the second shield can 472. For example, the first opening 423 and the second opening 424 may be spaced apart from the second shield can 472.

According to an embodiment of the disclosure, an interposer 430 may be disposed along a periphery of the second PCB 420. According to an embodiment of the disclosure, the first opening 423 formed on the fourth surface 422 may be spaced apart from the interposer 430 by a first distance or more. For example, a region 600 illustrated in FIG. 6A may indicate a position spaced apart from the interposer 430 by the first distance or more. The first opening 423 (and/or the second opening 424) may be positioned at a point in the region 600.

For example, in a case that the first opening 423 for insertion of the nozzle 530 is positioned too close from the interposer 430, damage to the interposer 430 may be caused by discharge pressure of the TIM 510 in a process into which the TIM 510 is injected. In a case that a distance between the first opening 423 and the interposer 430 is shorter than the first distance, a junction of the interposer 430 may be damaged by the discharge pressure of the TIM 510, when the TIM 510 is injected from the nozzle 530. Since an electrical connection between the first PCB 410 and the second PCB 420 may not be stably performed in a case that the interposer 430 is damaged, some functions of an electronic device 101 may not function properly or a current may leak. In order to reduce the damage to the interposer 430, a position of the first opening 423 on the fourth surface 422 may be spaced apart from the interposer 430 by the first distance or more.

For example, in a case that the first opening 423 for the insertion of the nozzle 530 is positioned too close from the interposer 430, the TIM 510 may leak through a gap between the interposer 430 and the second PCB 420 in the process into which the TIM 510 is injected. In a case that the distance between the first opening 423 and the interposer 430 is shorter than the first distance, the TIM 510 may leak into the gap between the second PCB 420 and the interposer 430. The leakage may cause a decrease in the TIM 510 included in the space between the first PCB 410 and the second PCB 420. As heat diffusion through a second thermal conduction path (e.g., the second thermal transfer path P2 of FIG. 5) may not be properly performed in a case that an amount of the TIM 510 included in the space is insufficient, a heat dissipation effect may be weakened, and a malfunction of the electronic device 101 by the leaked TIM 510 may be caused. In order to reduce the leakage of the TIM 510, the position of the first opening 423 on the fourth surface 422 may be spaced apart from the interposer 430 by the first distance or more.

According to one embodiment of the disclosure, the first distance may be approximately 3 mm or more. For example, on the fourth surface 422, the first opening 423 may be spaced apart from the interposer 430 by approximately 3 mm or more, but is not limited thereto. As the first opening 423 is spaced apart from the interposer 430 by approximately 3 mm or more, the damage to the interposer 430 due to the discharge pressure of the TIM 510 may be reduced in the process of injecting the TIM 510, and the leakage of the TIM 510 through the gap between the second PCB 420 and the interposer 430 may be reduced. According to an embodiment of the disclosure, as the distance between the first opening 423 and the interposer 430 is spaced apart by the first distance or more, the heat dissipation effect may be enhanced.

According to an embodiment of the disclosure, the second opening 424 may be formed on the fourth surface 422. An observation hole may be used to check a region to which the TIM 510 is applied or to check an injection amount of the TIM 510. For example, in an injection process of the TIM 510, through at least one sensor (e.g., the camera module 212 and a thermal conductivity meter), it may be checked whether a region into which the TIM 510 is injected corresponds a region within a designated region and/or whether an amount of the injected TIM 510 corresponds to a designated amount. For example, as a thickness of the TIM 510 is measured through the observation hole, it may be checked whether the TIM 510 has been injected in an appropriate amount.

According to an embodiment of the disclosure, the second opening 424 may be spaced apart from the first opening 423 by a second distance or more. For example, in a case that the second opening 424 is positioned too close from the first opening 423, it may be difficult to accurately inspect an injection position of the TIM 510 or the injection amount of the TIM 510. For example, as the injection process may be end in a state that the TIM 510 is not injected in the required amount when the second opening 424 is positioned within the second distance from the first opening 423, the injection amount of the TIM 510 may be insufficient. As the heat diffusion through a second thermal transfer path is not properly performed in a case that the injection amount of the TIM 510 is insufficient, the heat dissipation effect may be weakened. The second opening 424 may be spaced apart from the first opening 423 by the second distance or more such that the TIM 510 may be sufficiently injected into the space.

According to an embodiment of the disclosure, the second distance may be determined based on at least one of a process time during which the TIM 510 is injected into the space through the nozzle 530 or a viscosity of the TIM 510. In a case that the second opening 424 is too far away from the first opening 423, a timing of the injection amount of the TIM 510 identified through the second opening 424 corresponding to a designated injection amount may be delayed. As an injection process time of the TIM 510 is delayed in a case that the timing is delayed, a manufacturing time may be increased. For example, in a case that the process time into which the TIM 510 is injected through the nozzle 530 is set to approximately 20 seconds, a position of the second opening 424 may be set to a position capable of identifying that the TIM 510 has been sufficiently injected into the space, when the TIM 510 is injected for 20 seconds. For example, when the TIM 510 is injected for 20 seconds, the second distance may be set such that the injection amount of the TIM 510 identified through the second opening 424 may correspond to a range within a range of the designated injection amount.

The electronic device 101 according to an embodiment of the disclosure may include the second PCB 420 including the first opening 423 and the second opening 424, which have a position capable of securing the second thermal transfer path through the TIM 510. The first opening 423 may be spaced apart from the interposer 430 by the first distance or more, and the second opening 424 may be spaced apart from the first opening 423 by the second distance or more. As the position of the first opening 423 and the second opening 424 satisfies the conditions, the electronic device 101 according to an embodiment of the disclosure may include the PCB 400 including a sufficient amount of the TIM 510, and address issues due to the leakage of the TIM 510. According to an embodiment of the disclosure, as heat generated from the first electronic component 440 may be diffused not only through a first thermal transfer path (e.g., the first thermal transfer path P1 of FIG. 5) but also through the second thermal transfer path, the heat dissipation effect may be improved.

Referring to FIG. 6B, a second electronic component 450 may be disposed on the second surface 412 of the first PCB 410. A second portion 620 illustrated in FIG. 6B may be a region of the second surface 412 corresponding to a first portion (e.g., the first portion 610 of FIG. 5) on a first surface 411 on which the first electronic component 440 is disposed. For example, the first electronic component 440 may be in contact with the first portion 610 on the first surface 411. The second portion 620 may be a region on the second surface 412 facing the first portion 610. Since heat generated from the first electronic component 440 may be transferred to the TIM 510 through the first surface 411 and the second surface 412, a contact area between the TIM 510 and the second portion 620 may be required to be large to effectively transfer the heat. According to an embodiment of the disclosure, the TIM 510 may be in contact with approximately 85% or more of the second portion 620. For example, the TIM 510 injected between the first PCB 410 and the second PCB 420 may be in contact with 85% or more of the second portion 620. According to an embodiment of the disclosure, the TIM 510 may occupy 60% or more of a total volume of the space. In order to increase the contact area between the TIM 510 and the second portion 620 and increase a volume in the space occupied by the TIM 510, a viscosity of the TIM 510 may be approximately 70,000 CPS or less. The TIM 510 according to an embodiment of the disclosure may comprise a filler of 95 wt % or more to increase a heat dissipation effect. The TIM 510 according to an embodiment of the disclosure may comprise approximately 70 vol % to approximately 99 vol % of the filler. A particle size of the filler may be approximately 200 μm or less.

According to an embodiment of the disclosure, the TIM 510 comprises a filler comprising aluminum oxide (Al₂O₃) and aluminum nitride (AlN). Since the aluminum oxide and the aluminum nitride have high thermal conductivity, thermal conductivity of the TIM 510 may be improved. According to an embodiment of the disclosure, the TIM 510 comprising approximately 95 wt % or more of the filler may have thermal conductivity of 7 W/mk or more. As the TIM 510 has the thermal conductivity of 7 W/mk or more, the heat generated from the first electronic component 440 may be transferred in a second direction D2 along the second thermal transfer path. As a content of the filler is increased, the contact area capable of transferring heat may be increased, thereby improving the thermal conductivity.

As the content of the filler comprised in the TIM 510 exceeds approximately 95 wt %, the viscosity of the TIM may be improved and flowability of the TIM 510 may be decreased. In a case that the aluminum oxide and the aluminum nitride having the high thermal conductivity are comprised as the filler, an increase in the viscosity may be caused due to low density. For example, a case of the TIM 510 comprising approximately 95 wt % or more of the filler may indicate low flowability by having a viscosity of approximately 100,000 CPS or more. As the TIM 510 discharged from the nozzle 530 is not evenly spread into a space in a case that the viscosity of the TIM 510 is high and its flowability is low, a process of injecting the TIM 510 into the space may require a long time. In a case that the TIM 510 is not evenly spread into the space, the contact area between the TIM 510 and the second portion 620 may be decreased, and the volume in the space occupied by the TIM 510 may be decreased. The decrease in the area and the decrease in the volume may cause a weakening of the heat dissipation effect through the second thermal transfer path.

The TIM 510 according to an embodiment of the disclosure may include an additive and/or a dispersant for reducing the viscosity and improving the flowability. According to an embodiment of the disclosure, the TIM 510 may comprise polydimethylsiloxane forming liquid resin, and the polydimethylsiloxane may comprise a hydroxy functional group. For example, a chemical formula of the polydimethylsiloxane is CH₃[Si(CH₃)₂O]ₙSi(CH₃)₃. In the chemical formula, the n may be 10 to 100,000. According to an embodiment of the disclosure, the polydimethylsiloxane comprised in the TIM 510 may comprise the hydroxy functional group as a methyl group (CH₃) is substituted with the hydroxy functional group or a hydrogen (H) of the methyl group is substituted with the hydroxy functional group. However, it is not limited thereto. The hydroxy functional group may cause effective dispersion of the filler in resin by causing attraction between the filler. As the filler may not be well dispersed in the resin in a case that the polydimethylsiloxane does not comprise the hydroxy functional group, the viscosity may be increased and the flowability may be lowered.

According to an embodiment of the disclosure, the TIM 510 may comprise at least one of a poly carboxylic acid-based dispersant, an ammonium-based dispersant, an alkylamine-based dispersant, and a silicone-based surfactant as a dispersant. The dispersant may reduce a viscosity of a thermal interface material and improve its flowability by evenly dispersing the filler in the resin. According to an embodiment of the disclosure, the TIM 510 may comprise a plasticizer for improving the flowability.

The following Table 1 indicates characteristics of the TIM 510 according to an embodiment of the disclosure and TIMs according to a comparative example. In the following Table 1, the embodiment includes the polydimethylsiloxane comprising the hydroxy functional group, and the comparative example does not include the polydimethylsiloxane comprising the hydroxy functional group.

TABLE 1

| | | Hydroxy | Thermal [symbol] | | |
|---|---|---|---|---|---|
| | | functional [symbol] | conductivity [symbol] | Viscosity [symbol] | Flowability [symbol] |
| | Filler [symbol] | group [symbol] | (W/m · K) | (CPS) | (g/min) |
| Embodiment | Al₂O₃, AIN | Included [symbol] | 7.1 | 70,000 | 9.6 |
| Comparative | Al₂O₃, AIN | Not included [symbol] | 7.0 | 152,000 | 4.2 |
| example | *Al₂O₃, MgO | Included [symbol] | 6.4 | 115,000 | 8.0 |
| | Al₂O₃, MgO | Not included [symbol] | 6.5 | 194,000 | 2.1 |
| | Al₂O₃, BN | Included [symbol] | 6.9 | 152,200 | 6.3 |
| | Al₂O₃, BN | Not included [symbol] | 7.0 | 270,300 | 0.8 |

In the Table 1, the thermal conductivity was measured based on ASTM D5470 (Linseis, BLT70 μm, Sample temp. 20° C.). The viscosity was measured based on ASTM D2196 (Brookfield HADV-YU, Spindle #7, 30 rpm, 25° C.). The flowability was measured based on Joinset Method (Ban seok Dispenser TAD-200S, BPN-14 G Nozzle tip, 25 psi).

Referring to the Table 1, the TIM 510 comprising the filler according to an embodiment of the disclosure may have high thermal conductivity (7.1 W/mk) by comprising approximately 95 wt % of the aluminum oxide and the aluminum nitride. In a case of the TIMs 510 according to the comparative example, since they comprise a filler having the high thermal conductivity, but do not comprise the polydimethylsiloxane comprising the hydroxy functional group, they may have a high viscosity and a low flowability. The TIM 510 according to an embodiment of the disclosure may have a relatively low viscosity and a relatively high flowability, while also having a relatively high thermal conductivity. According to an example, the TIM 510 may have a high heat dissipation effect through the second thermal transfer path by a high thermal conductivity, a low viscosity, and a high flowability.

According to an embodiment of the disclosure, the TIM 510, which is a curing type, may not require a separate curing process after being injected into the PCB 400. Since at least some of the TIMs according to the comparative example require a heat curing process performed at approximately 135° C. for approximately 7 minutes, a manufacturing process may be simplified in a case that the TIM according to an embodiment is used. Since the TIM 510 of the curing type may be stored at a room temperature, a problem caused by a change in physical properties due to temperature may be addressed.

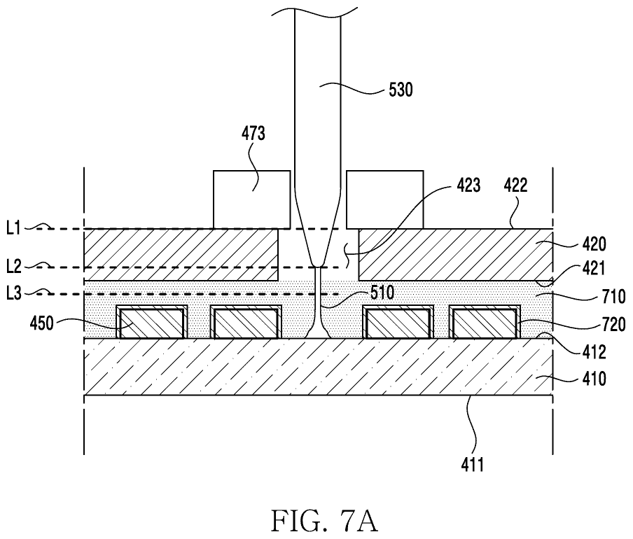

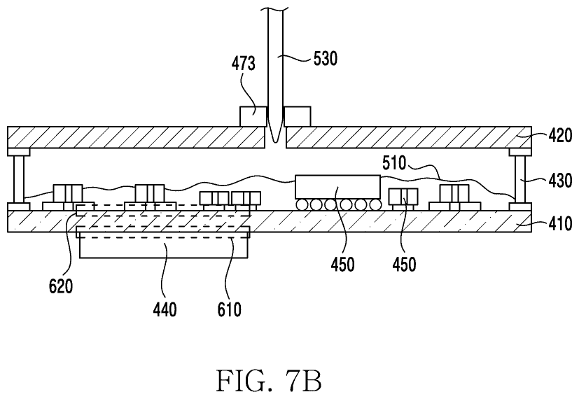

FIGS. 7A and 7B illustrate a process into which a thermal interface material is injected according to various embodiments of the disclosure.

FIG. 7A indicates a state in which a nozzle 530 is inserted and injected into a first opening 423.

Referring to FIG. 7A, the nozzle 530 may be inserted inside a second printed circuit board 420 through the first opening 423. The first opening 423 may be covered by a sealing member 473. The nozzle 530 may be inserted inside the first opening 423 by pushing a cutout portion of the sealing member 473.

According to an embodiment of the disclosure, a second electronic component 450 may be positioned in a space between a first PCB 410 and the second PCB 420 by being disposed on a second surface 412 of the first PCB 410. The second electronic component 450 may include a plurality of electronic components. For example, the second electronic component 450 may include a plurality of passive elements, but is not limited thereto. The second electronic component 450 positioned in the space may occupy a portion of the space. The portion occupied by the second electronic component 450 in the space may be referred to as a first region 710. In the space, a region different from the first region 710 may be referred to as a second region 720. For example, the second region 720 may be an empty region that is not occupied by the second electronic component 450.

For example, in a case that the first opening 423 corresponds to the first region 710, the second electronic component 450 may be damaged by the nozzle 530, when the nozzle 530 is inserted through the first opening 423. In a case that the first opening 423 and the first region 710 overlap, the second electronic component 450 may be positioned under the first opening 423. When the nozzle 530 is inserted into the space through the first opening 423, the nozzle 530 may be in contact with the second electronic component 450. As the damage to the second electronic component 450 is caused or an outlet of the nozzle 530 is blocked by the second electronic component 450 in a case that the nozzle 530 is in contact with the second electronic component 450, smoothly discharge of a thermal interface material 510 may be difficult.

According to an embodiment of the disclosure, the first opening 423 may correspond to the second region 720. The first opening 423 corresponding to the second region 720 may be referred as the first opening 423 overlapping the second region 720 or the first opening 423 being arranged with the second region 720. A region of the space to which the first opening 423 faces may be the second region 720 that is not occupied by the second electronic component 450. The first opening 423 does not overlap the second electronic component 450 positioned in the space. As the second opening 424 for insertion of the nozzle 530 corresponds to the second region 720, the nozzle 530 may not be in contact with the second electronic component 450 even when passing through the second opening 424. According to an embodiment of the disclosure, as the nozzle 530 and the second electronic component 450 are not in contact with each other, the damage to the second electronic component 450 may be prevented, and the TIM 510 may be smoothly discharged from the nozzle 530. For example, in a case that the second electronic component 450 includes the plurality of electronic components, the first opening 423 may correspond to a space between the plurality of electronic components.

According to an embodiment of the disclosure, an insertion depth of the nozzle 530 may be adjusted. Referring to FIG. 7A, a first straight line L1 may be a virtual line corresponding to a fourth surface 422 of the second PCB 420. A second straight line L2 may be a virtual line corresponding to the inside of the second PCB 420. A third straight line L3 may be a virtual line positioned closer to a third surface 421 than a height of the second electronic component 450. According to an embodiment of the disclosure, when the nozzle 530 is inserted through the first opening 423 to inject the TIM 510, an end of the nozzle 530 may be positioned between the second straight line L2 and the third straight line L3. For example, a device that controls an operation of the nozzle 530 may control the nozzle 530 such that the nozzle 530 is positioned between the second straight line L2 and the third straight line L3. The TIM 510 may be discharged from the nozzle 530 in a state in which the nozzle 530 is positioned between the second straight line L2 and the third straight line L3. As the end of the nozzle 530 is inserted to be positioned between the second straight line L2 and the third straight line L3, a reverse flow of the TIM 510 through the first opening 423 may be reduced, and a flow resistance of the TIM 510 may be decreased.

FIG. 7B indicates a state in which injection of the TIM 510 from the nozzle 530 is completed.

Referring to FIG. 7B, as the TIM 510 is discharged from the nozzle 530, at least a portion of a space covered by the first PCB 410, the second PCB 420, and an interposer 430 may be filled with the TIM 510. Since the TIM 510 according to an embodiment comprises polydimethylsiloxane comprising a hydroxy functional group, the TIM 510 may have a relatively low viscosity and a relatively high flowability. The TIM 510 discharged from the nozzle 530 may be diffused into the space. Since wettability of the TIM 510 may be increased by the hydroxy functional group, the TIM 510 having the relatively high flowability may be diffused while filling the space. For example, in a case that a time of an injection process of the TIM 510 is set within approximately 20 seconds, the TIM 510 may fill approximately 60% or more of the space after the process ends. However, it is not limited thereto. According to a form of a PCB 400, the TIM 510 may also fill approximately 90% or more of the space. In a case that an injection amount of the TIM 510 is approximately 1.6 g or more, the TIM 510 may fill approximately 62% or more of the space, and may be in contact with approximately 86% or more of a second portion 620, corresponding to a first portion 610 in contact with the first electronic component 440. In a case that the injection amount of the TIM 510 is approximately 2 g or more, the TIM 510 may be in contact with approximately 99% or more of the second portion 620.

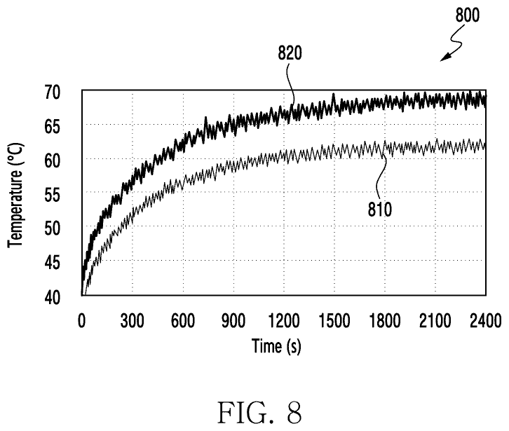

FIG. 8 is a graph indicating a temperature change of a first electronic component according to an embodiment of the disclosure.

Referring to FIG. 8, an x-axis of a graph 800 is a time (unit: seconds) and a y-axis is a temperature (unit: degrees Celsius temperature (° C.)). A first graph 810 of FIG. 8 indicates a temperature change of a first electronic component 440 included in an electronic device 101 according to an embodiment when a game application is executed. The electronic device 101 according to an embodiment of the disclosure may include a printed circuit board 400 having the above-described structure and the above-described thermal interface material 510.

A second graph 820 of FIG. 8 indicates a temperature change of a first electronic component included in an electronic device according to a comparative example when the game application is executed. The electronic device according to the comparative example may be referred to as a device including a TIM comprising a thermally conductive filler of approximately 89 wt % or less and not comprising polydimethylsiloxane comprising a hydroxy functional group.

When the first graph 810 and the second graph 820 are compared, a difference in temperature change over time may be confirmed. As an operating time elapses, a temperature increasing rate of the second graph 820 may be higher than a temperature increasing rate of the first graph 810. Referring to the first graph 810, while approximately 2400 seconds elapse from an initial time (0 seconds), in a case of the electronic device 101 according to an embodiment of the disclosure, a temperature of the first electronic component 440 may be identified as approximately 60° C. to approximately 65° C. Referring to the second graph 820, while approximately 2400 seconds elapse from the initial time (0 seconds), and in a case of the electronic device according to the comparative example, a temperature of the first electronic component may be indicated as approximately 70° C. When approximately 2,400 seconds elapse, a difference in temperature to which the first graph 810 and the second graph 820 indicate may be approximately 7° C. The following Table 2 indicates a front temperature, a rear temperature, and a consumption current of a housing 210 when the game application is executed for the electronic device 101 according to an embodiment and the electronic device according to the comparative example.

TABLE 2

| | Front | Rear | Consumption |
|---|---|---|---|
| | temperature | temperature | current |
| | (° C.) | (° C.) | (mA) |
| Comparative | 46 | 43.7 | 971.3 |
| example | | | |
| Embodiment | 45.1 | 43.9 | 944.9 |
| Difference | −0.9 | +0.2 | −26.4 |

Referring to the Table 2, the front temperature of the electronic device 101 according to an embodiment of the disclosure may be approximately 0.9° C. lower than the front temperature of the electronic device according to the comparative example. The rear temperature of the electronic device 101 according to an embodiment of the disclosure may be approximately 0.2° C. higher than the rear temperature of the electronic device according to the comparative example. Since heat generated from the first electronic component 440 may be effectively diffused through a second thermal transfer path, an increase in the front temperature may be small. Since a display 201 is positioned on the front surface, performance deterioration of the display 201 may be decreased. The consumption current of the electronic device 101 according to an embodiment of the disclosure may be approximately 26.4 mA lower than the consumption current of the electronic device according to the comparative example. As an overall temperature of the electronic device 101 is decreased, the consumption current may be decreased, thereby improving power efficiency.

In the electronic device 101 according to an embodiment of the disclosure, since the second thermal transfer path may be effectively formed by the TIM 510 filled inside the PCB 400, a heat dissipation effect may be improved. Since the TIM 510 has a relatively high flowability, the second thermal transfer path through which a portion of the heat generated from the first electronic component 440 is conducted may be strongly formed. As heat is conducted through a first thermal transfer path and the second thermal transfer path, a temperature increase of the first electronic component 440 may be relatively suppressed. According to an embodiment of the disclosure, as a heat dissipation effect on the first electronic component 440 is improved, operation performance of the first electronic component 440 may be improved, and damage due to heat generation may be reduced.

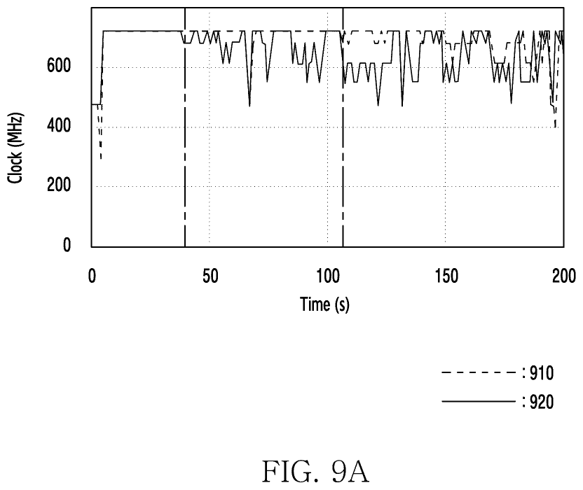

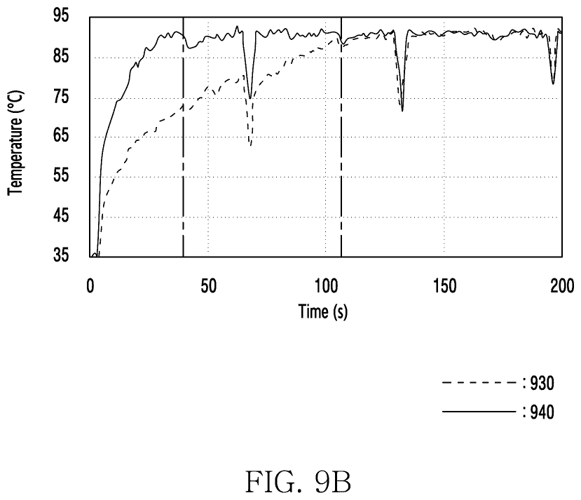

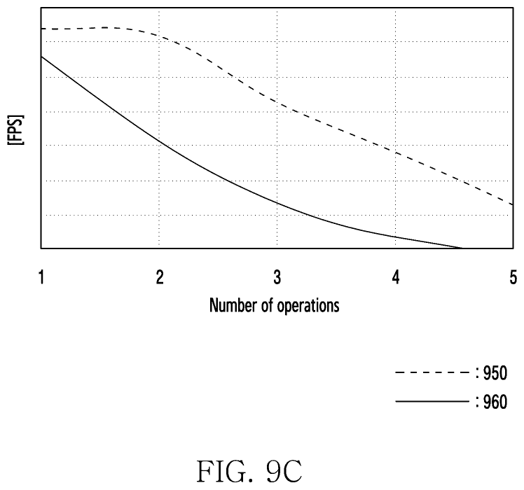

FIG. 9A is a graph indicating a clock of a first electronic component according to an embodiment of the disclosure. FIG. 9B is a graph indicating a temperature change of a first electronic component according to an embodiment of the disclosure. FIG. 9C is a graph indicating an FPS of a display according to an embodiment of the disclosure.

According to an embodiment of the disclosure, a first electronic component 440 may include a GPU. For example, the GPU may be implemented as circuitry logically divided in the first electronic component 440 or a component physically separated from the first electronic component 440. The GPU may perform a graphic calculation for visual information displayed through a display 201. A clock is a frequency of the GPU, and as the clock of the GPU is higher, an amount of speed of the calculation by the GPU may be increased, and a heat generation may be increased. In the following description, the first electronic component 440 is described as the GPU, but is not limited thereto.

An x-axis of the graph of FIG. 9A is a time (unit: seconds), and a y-axis is the clock (unit: MHz) of the GPU. Referring to FIG. 9A, the GPU may perform throttling. For example, when a temperature of the GPU reaches a threshold temperature, the GPU may reduce the heat generation by lowering a voltage and the clock.

A first graph 910 of FIG. 9A indicates the clock of the first electronic component 440 (e.g., the GPU) of an electronic device 101 according to an embodiment. A second graph 920 of FIG. 9A indicates the clock of the first electronic component of an electronic device according to a comparative example. When the first graph 910 and the second graph 920 are compared, a first throttling timing T1 of the first graph 910 may be delayed compared to a second throttling timing T2 of the second graph 920. For example, the first throttling timing T1 may be delayed by approximately 64 seconds compared to the second throttling timing T2, but is not limited thereto. As described with reference to FIG. 8, since a temperature increasing rate of the first electronic component 440 included in the electronic device 101 according to an embodiment is slower than a temperature increasing rate of the first electronic component included in the electronic device according to the comparative example, a throttling timing may be delayed.

An x-axis of the graph of FIG. 9B is a time (unit: seconds), and a y-axis is the temperature (unit: degrees Celsius temperature (° C.)) of the GPU. Referring to FIG. 9B, a temperature change of the GPU may be caused according to a clock timing of the GPU.

A third graph 930 of FIG. 9B indicates a temperature over time of the first electronic component 440 (e.g., the GPU) of the electronic device 101 according to an embodiment. A fourth graph 940 of FIG. 9B indicates a temperature over time of the first electronic component of the electronic device according to the comparative example. When the third graph 930 and the fourth graph 940 are compared, a second throttling timing T2 may be faster than the first throttling timing T1 since a timing at which the second graph reaches the threshold temperature (e.g., approximately 90° C.) is faster than the first graph. For example, at the second throttling timing T2, the third graph 930 may indicate the threshold temperature, but the fourth graph 940 may indicate a temperature lower than the threshold temperature at the second throttling timing T2. For example, at the second throttling timing T2, a difference between the temperature indicated by the third graph 930 and the temperature indicated by the fourth graph 940 may be approximately 17° C., but is not limited thereto. In a case that the clock of the GPU is decreased due to the throttling, a quality of the visual information displayed on the display 201 may be deteriorated. As described with reference to FIG. 9A, since the first throttling timing T1 is delayed by approximately 64 seconds compared to the second throttling timing T2, the electronic device 101 according to an embodiment of the disclosure may provide high performance of the display 201.

An x-axis of the graph of FIG. 9C is a time (unit: seconds), and a y-axis is a frame per second (FPS) of the display 201. Referring to FIG. 9C, a difference in the FPS of the display 201 may be caused according to the temperature and the throttling of the GPU.

A fifth graph 950 of FIG. 9C indicates the frame per second (FPS) of the display 201 of the electronic device 101 according to an embodiment according to the number of operations. A sixth graph 960 of FIG. 9C indicates the FPS of the display 201 of the electronic device according to the comparative example. Referring to the fifth graph 950 and the sixth graph 960, the fifth graph 950 may indicate a higher FPS than the sixth graph 960. In the electronic device 101 according to an embodiment of the disclosure, since a temperature increasing rate of the GPU is relatively slow, a throttling timing may be delayed. Since the quality of the visual information displayed through the display 201 is based on the clock of the GPU, the electronic device 101 according to an embodiment of the disclosure may provide visual information of higher quality than the electronic device according to the comparative example.

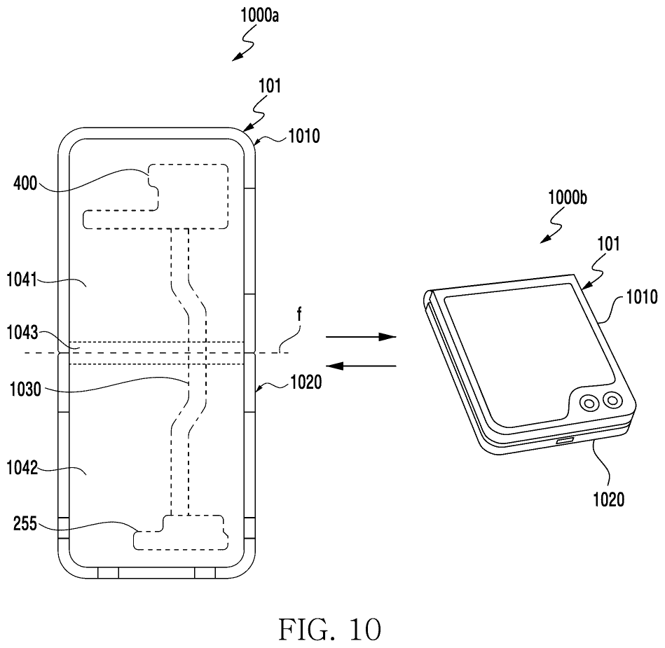

FIG. 10 illustrates an electronic device according to an embodiment of the disclosure.

Referring to FIG. 10, the above-described electronic device 101 has been described as an electronic device including a bar-shaped housing 210, but a form factor of the electronic device 101 is not limited thereto. For example, the electronic device 101 may also be implemented as a foldable device or a slidable device. The above-described descriptions may be applied to a printed circuit board 400 included in the foldable device or the slidable device. The electronic device 101 described below is an electronic device including the housing 210 having a foldable structure, and may be substantially the same as the electronic device 101 described above except for the structure of the housing 210. The same components as the above-described components may be given the same reference numerals, and overlapping descriptions may be omitted.

Referring to FIG. 10, the electronic device 101 according to an embodiment of the disclosure may include a foldable housing 1001. The foldable housing 1001 may include a first housing 1010 and a second housing 1020. The first housing 1010 and the second housing 1020 may be rotatably coupled by a hinge assembly. For example, the first housing 1010 may be rotatable with respect to the second housing 1020 based on a folding axis f. For example, the electronic device 101 may be configured to provide a first state 1000a in which the first housing 1010 and the second housing 1020 are unfolded, a second state 1000b in which the first housing 1010 and the second housing 1020 are folded, and a plurality of intermediate states between the first state 1000a and the second state 1000b.

According to an embodiment of the disclosure, a display 1040 may include a first display region 1041, a second display region 1042, and a third display region 1043. The first display region 1041 may be supported by the first housing 1010. The second display region 1042 may be supported by the second housing 1020. The third display region 1043 may be disposed between the first display region 1041 and the second display region 1042. The third display region 1043 may be at least partially bent based on rotation of the first housing 1010 or the second housing 1020. The display 1040 may be referred to as a flexible display.

The electronic device 101 according to an embodiment of the disclosure may include the PCB 400 and a sub-PCB 400. For example, the PCB 400 may be disposed in the first housing 1010. The sub-PCB 400 may be disposed in the second housing 1020. A first PCB 410 and a second PCB 420 may be electrically connected through a connection member (e.g., a flexible PCB) 1030.

According to an embodiment of the disclosure, each of the first housing 1010 and the second housing 1020 may have an inner space narrower than the housing 210 illustrated in FIG. 2. Heat dissipation of electronic components disposed in the narrow inner space may be important. As described above, the PCB 400 may be a stacked type substrate and may include a thermal interface material 510.

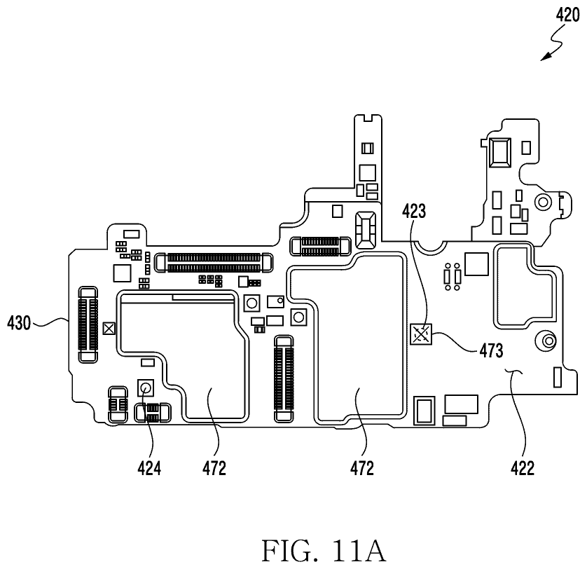

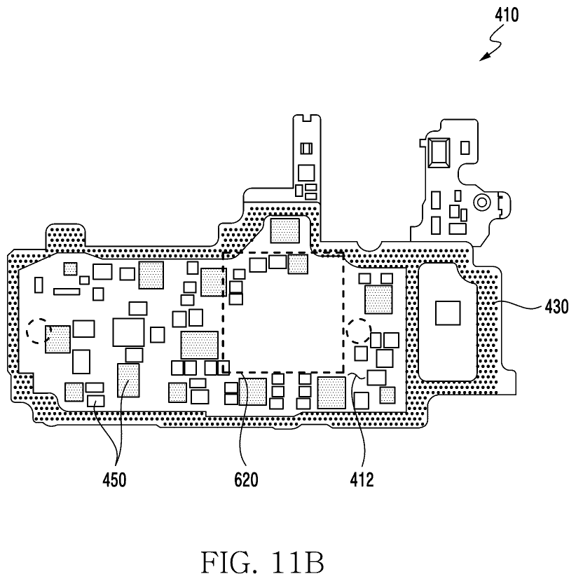

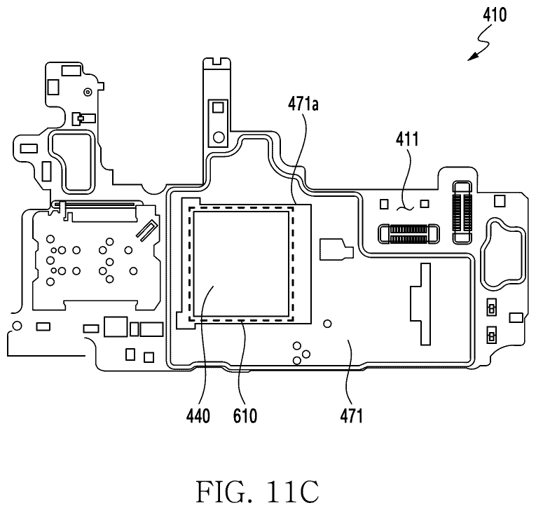

FIG. 11A is a front view of a fourth surface of a second printed circuit board according to an embodiment of the disclosure. FIG. 11B is a front view of a second surface of a first printed circuit board according to an embodiment of the disclosure. FIG. 11C is a front view of a first surface of a first printed circuit board according to an embodiment of the disclosure.

Referring to FIGS. 11A, 11B, and 11C, the above-described descriptions may be applied to a PCB 400 of an electronic device 101 including a foldable housing 1001 in substantially the same manner.

According to an embodiment of the disclosure, a second PCB 420 may include a first opening 423 and a second opening 424. The first opening 423 may be spaced apart from an interposer 430 by a first distance or more. As the first opening 423 is spaced apart from the interposer 430 by the first distance or more, damage to the interposer 430 due to discharge pressure of a thermal interface material 510 may be decreased, and leakage of the TIM 510 through a gap between the interposer 430 and the second PCB 420 may be decreased. According to an embodiment of the disclosure, the first opening 423 and the second opening 424 may be spaced apart from a second shield can 472.

According to an embodiment of the disclosure, the first opening 423 may correspond to a second region 720 different from a first region 710 occupied by a second electronic component 450. For example, the first opening 423 may overlap the second region 720 or may be arranged with the second region 720. For example, the second electronic component 450 may include a plurality of electronic components, and the first opening 423 may correspond to a space between the plurality of electronic components.

According to an example, the TIM 510 may comprise approximately 95 wt % or more of a thermally conductive filler for high thermal conductivity. The thermally conductive filler may comprise aluminum oxide and aluminum nitride. The TIM 510 may have thermal conductivity of approximately 7 W/mk or more.

The TIM 510 according to an embodiment of the disclosure may comprise polydimethylsiloxane comprising a hydroxy functional group. The TIM 510 may have a viscosity of approximately 70,000 CPS or less. Due to the polydimethylsiloxane comprising the hydroxy functional group, flowability of the TIM 510 may be relatively high.

The TIM 510 according to an embodiment of the disclosure may comprise at least one of a poly carboxylic acid-based dispersant, an ammonium-based dispersant, an alkylamine-based dispersant, or a silicone-based surfactant. The TIM 510 may fill approximately 90% or more of a space between the first PCB 410 and the second PCB 420. The TIM 510 may be in contact with approximately 86% or more of a second portion 620 of a second surface 412 corresponding to a first portion 610 of a first surface 411 in contact with a first electronic component 440.

An electronic device 101 is provided. The electronic device 101 may include a housing 210 including a first plate 202 facing a first direction D1, and a second plate 211 facing a second direction D2 opposite to the first direction D1. The electronic device 101 may include a first printed circuit board (PCB) 410 disposed in the housing 210, the first PCB including a first surface 411 facing the first direction D1, and a second surface 412 facing the second direction D2. The electronic device 101 may include a second PCB 420 spaced apart from the first PCB 410 in the second direction D2, the second PCB including a third surface 421 facing the first direction D1, and a fourth surface 422 facing the second direction D2. The electronic device 101 may include an interposer 430, disposed between the first PCB 410 and the second PCB 420, forming a space between the first PCB 410 and the second PCB 420. The electronic device 101 may include a first electronic component 440 disposed on the first surface 411. The electronic device 101 may include a second electronic component 450, disposed on the second surface 412, occupying a first region 710 of the space. The electronic device 101 may include a thermal interface material (TIM) 510 included in the space. The second PCB 420 may include a first opening 423, corresponding to a second region 720 of the space different from the first region 710 occupied by the second electronic component 450, for insertion of a nozzle 530 for injection of the TIM 510. According to an embodiment of the disclosure, the first opening 423 corresponding to the second region 720 may be referred to as a structure in which the first opening 423 does not overlap the second electronic component 450 when the first opening 423 is viewed from above. As the first opening 423 corresponds to the second region 720, when the nozzle 530 is inserted into the first opening 423, damage to the second electronic component 450 by the nozzle 530 may be reduced, and the TIM 510 may be discharged smoothly.

For example, the first opening 423 may be spaced apart from the interposer 430 by a first distance or more. According to an embodiment of the disclosure, in a case that the first opening 423 is too close from the interposer 430, the interposer 430 may be damaged by discharge pressure of the nozzle 530, or the TIM 510 may leak through a gap. As the first opening 423 is spaced apart from the interposer 430 by the first distance or more, the damage to the interposer 430 and the leakage of the TIM 510 may be reduced.

For example, the first distance may be 3 mm or more.

For example, the second PCB 420 may include a second opening 424, for inspecting an injection state of the TIM 510, spaced apart from the first opening 423 by a second distance or more.

For example, the second distance may be set based on a process time in which the TIM 510 is injected into the space through the nozzle 530.

For example, the second electronic component 450 may include a plurality of electronic components. The first opening 423 may correspond to a space between the plurality of electronic components.

For example, the electronic device 101 may include a third electronic component 460 disposed on the fourth surface 422. The electronic device 101 may include a shield can (e.g., the second shield can 472), disposed on the fourth surface 422, covering the third electronic component 460. The first opening 423 may be spaced apart from the shield can.

For example, the TIM 510 may form a thermal transfer path (e.g., the second thermal transfer path P2) for transferring heat generated from the first electronic component 440 in the second direction D2.

For example, the electronic device 101 may include another shield can, disposed on the first surface 411, covering the first electronic component 440, and including a third opening 471a facing the first electronic component 440. The electronic device 101 may include another TIM 520a disposed on the first electronic component 440. The other TIM 520a may form another thermal transfer path (e.g., the first thermal transfer path P1) for transferring heat generated from the first electronic component 440 in the first direction D1.

For example, a volume of a portion of the space occupied by the TIM 510 may be 60% or more of a total volume of the space.

For example, the TIM 510 may be in contact with 85% or more of a second portion 620 on the second surface 412 corresponding to a first portion 610 on the first surface 411 on which the first electronic component 440 is disposed.

For example, the TIM 510 may comprise a filler comprising aluminum oxide (Al₂O₃) and aluminum nitride (AlN). The TIM 510 may comprise 95 wt % or more of the filler. Thermal conductivity of the TIM 510 may be 7 W/mK or more.

For example, the TIM 510 may comprise polydimethylsiloxane comprising a hydroxy functional group.

For example, the TIM 510 may comprise at least one of a poly carboxylic acid-based dispersant, an ammonium-based dispersant, an alkylamine-based dispersant, or a silicone-based surfactant.

For example, the TIM 510 may have a viscosity of 70,000 CPS or less.

According to an embodiment of the disclosure, as a content of the filler comprised in the TIM 510 exceeds approximately 95 wt %, the thermal conductivity may be improved. Since the thermal conductivity of the TIM 510 is improved, diffusion of the heat generated from the first electronic component 440 may be effectively performed, thereby reducing overheating of the first electronic component 440 and decreasing performance deterioration of a display 201. The TIM 510 according to an embodiment of the disclosure may comprise an additive and/or a dispersant for decreasing the viscosity and improving flowability. According to an embodiment of the disclosure, the TIM 510 may comprise polydimethylsiloxane forming a liquid resin, and the polydimethylsiloxane may comprise the hydroxy functional group. The hydroxy functional group may cause effective dispersion of the filler in the resin by causing attraction between the fillers. The TIM 510 may comprise at least one of the poly carboxylic acid-based dispersant, the ammonium-based dispersant, the alkylamine-based dispersant, or the silicone-based surfactant as the dispersant. The dispersant may reduce the viscosity of a thermal interface material and improve its flowability, by evenly dispersing the filler in the resin. According to an embodiment of the disclosure, the TIM 510 may comprise a plasticizer for improving the flowability.

An electronic device 101 is provided. The electronic device 101 may include a first printed circuit board 410. The electronic device 101 may include a second PCB 420 spaced apart from the first PCB 410. The electronic device 101 may include an interposer 430 disposed between the first PCB 410 and the second PCB 420 and forming a space between the first PCB 410 and the second PCB 420. The electronic device 101 may include a TIM 510 included in the space. The second PCB 420 may be spaced apart from the interposer 430 by a first distance or more and may include a first opening 423 for insertion of a nozzle 530 for injection of the TIM 510.

For example, the first distance may be 3 mm or more.

For example, the electronic device 101 may be disposed on the first PCB 410 and may include a first electronic component 440 outside the space. The electronic device 101 may include a second electronic component 450 disposed on the second PCB 420 and positioned in the space. The first opening 423 may correspond to a remaining portion of the space different from a portion of the space occupied by the second electronic component 450.

For example, the second PCB 420 may include a second opening 424, for inspecting an injection state of the TIM 510, spaced apart from the first opening 423 by a second distance or more.

For example, the electronic device 101 may include a display 201 at least partially forming a front surface of the electronic device 101. The electronic device 101 may include a housing 210 including a first plate 202 supporting the display 201 and a second plate 211 at least partially forming a rear surface of the electronic device 101. The first PCB 410 and the second PCB 420 may be disposed in the housing 210. The TIM 510 may form a thermal transfer path for transferring heat generated from the first electronic component 440 in a direction toward the second plate 211.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. As used herein, each of such phrases as “A or B,” “at least one of A and B,” “at least one of A or B,” “A, B, or C,” “at least one of A, B, and C,” and “at least one of A, B, or C,” may include any one of or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” or “connected with” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment of the disclosure, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between a case in which data is semi-permanently stored in the storage medium and a case in which the data is temporarily stored in the storage medium.

According to an embodiment of the disclosure, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments of the disclosure, each component (e.g., a module or a program) of the above-described components may include a single entity or multiple entities, and some of the multiple entities may be separately disposed in different components. According to various embodiments of the disclosure, one or more of the above-described components may be omitted, or one or more other components may be added. Alternatively or additionally, a plurality of components (e.g., modules or programs) may be integrated into a single component. In such a case, according to various embodiments of the disclosure, the integrated component may still perform one or more functions of each of the plurality of components in the same or similar manner as they are performed by a corresponding one of the plurality of components before the integration. According to various embodiments of the disclosure, operations performed by the module, the program, or another component may be carried out sequentially, in parallel, repeatedly, or heuristically, or one or more of the operations may be executed in a different order or omitted, or one or more other operations may be added.

No claim element is to be construed under the provisions of 35 U.S.C. § 112, sixth paragraph, unless the element is expressly recited using the phrase “means for” or “means.”

It will be appreciated that various embodiments of the disclosure according to the claims and description in the specification can be realized in the form of hardware, software or a combination of hardware and software.

Any such software may be stored in non-transitory computer readable storage media. The non-transitory computer readable storage media store one or more computer programs (software modules), the one or more computer programs include computer-executable instructions that, when executed by one or more processors of an electronic device, cause the electronic device to perform a method of the disclosure.

Any such software may be stored in the form of volatile or non-volatile storage, such as, for example, a storage device like read only memory (ROM), whether erasable or rewritable or not, or in the form of memory, such as, for example, random access memory (RAM), memory chips, device or integrated circuits or on an optically or magnetically readable medium, such as, for example, a compact disk (CD), digital versatile disc (DVD), magnetic disk or magnetic tape or the like. It will be appreciated that the storage devices and storage media are various embodiments of non-transitory machine-readable storage that are suitable for storing a computer program or computer programs comprising instructions that, when executed, implement various embodiments of the disclosure. Accordingly, various embodiments provide a program comprising code for implementing apparatus or a method as claimed in any one of the claims of this specification and a non-transitory machine-readable storage storing such a program.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. An electronic device comprising:
a housing;
a first printed circuit board (PCB) disposed in the housing, the first PCB including:
a first surface facing a first direction, and
a second surface facing a second direction opposite to the first direction;
a second PCB, disposed in the housing, spaced apart from the first PCB in the second direction, the second PCB including:
a third surface facing the first direction, and
a fourth surface facing the second direction,
an interposer, disposed between the first PCB and the second PCB to electrically connect the first PCB and the second PCB, defining a space between the first PCB and the second PCB;
a first electronic component disposed on the first surface of the first PCB;
a second electronic component, disposed on the second surface of the first PCB, occupying a first region of the space; and
a thermal interface material (TIM) included in the space,
wherein the second PCB defines a first opening, corresponding to a second region of the space different from the first region of the space occupied by the second electronic component, for insertion of a nozzle for injection of the TIM.

2. The electronic device of claim 1, wherein the first opening is spaced apart from the interposer by a first distance or more.

3. The electronic device of claim 2, wherein the first distance is 3 mm or more.

4. The electronic device of claim 1, wherein the second PCB defines a second opening, for inspecting an injection state of the TIM, spaced apart from the first opening by a second distance or more.

5. The electronic device of claim 4, wherein the second distance is set based on a process time in which the TIM is injected into the space through the nozzle.

6. The electronic device of claim 1,
wherein the second electronic component includes a plurality of electronic components, and
wherein the first opening corresponds to a space between the plurality of electronic components.

7. The electronic device of claim 1, further comprising:
a third electronic component disposed on the fourth surface of the second PCB; and
a shield can disposed on the fourth surface of the second PCB to cover the third electronic component,
wherein the first opening is spaced apart from the shield can.

8. The electronic device of claim 1, wherein the TIM forms a thermal transfer path for transferring heat generated from the first electronic component in the second direction.

9. The electronic device of claim 1, further comprising:
another shield can, disposed on the first surface, covering the first electronic component, and including a third opening facing the first electronic component; and
another TIM disposed on the first electronic component,
wherein the other TIM forms another thermal transfer path for transferring heat generated from the first electronic component in the first direction.

10. The electronic device of claim 1, wherein a volume of a portion of the space occupied by the TIM is 60% or more of a total volume of the space.

11. The electronic device of claim 1, wherein the TIM is in contact with 85% or more of a second portion on the second surface corresponding to a first portion on the first surface on which the first electronic component is disposed.

12. The electronic device of claim 1,
wherein the TIM comprises a filler comprising aluminum oxide (Al₂O₃) and aluminum nitride (AlN),
wherein the TIM comprises 95 wt % or more of the filler, and
wherein thermal conductivity of the TIM is 7 W/mK or more.

13. The electronic device of claim 1, wherein the TIM comprises polydimethylsiloxane comprising a hydroxy functional group.

14. The electronic device of claim 13, wherein the TIM comprises at least one of a poly carboxylic acid-based dispersant, an ammonium-based dispersant, an alkylamine-based dispersant, or a silicone-based surfactant.

15. The electronic device of claim 1, wherein the TIM has a viscosity of 70,000 CPS or less.

16. An electronic device comprising:
a housing;
a first printed circuit board (PCB) disposed in the housing;
a second PCB, disposed in the housing, spaced apart from the first PCB;
an interposer, disposed between the first PCB and the second PCB to electrically connect the first PCB and the second PCB, wherein an internal volume is defined by the first PCB, the second PCB, and the interposer; and
a thermal interface material (TIM) positioned in the internal volume,
wherein the second PCB defines a first through hole, spaced apart from the interposer by a first distance or more, for insertion of a nozzle for injection of the TIM.

17. The electronic device of claim 16, wherein the first distance is 3 mm or more.

18. The electronic device of claim 16, further comprising:
a first electronic component, mounted on the first PCB, positioned out of the internal volume; and
a second electronic component, mounted on the second PCB, positioned in the internal volume,
wherein the first through hole corresponds to a portion of the internal volume, different from a portion of the internal volume occupied by the second electronic component.

19. The electronic device of claim 16, wherein the second PCB defines a second through hole, for inspecting an injection state of the TIM, spaced apart from the first through hole by a second distance or more.

20. A printed circuit board (PCB) assembly comprising:
a first PCB including:
a first surface facing a first direction, and
a second surface facing a second direction opposite to the first direction;
a second PCB, spaced apart from the first PCB in the second direction, the second PCB including:
a third surface facing the first direction, and
a fourth surface facing the second direction, wherein the second surface of the first PCB and the third surface of the second PCB face to each other;
an interposer, disposed between the first PCB and the second PCB to electrically connect the first PCB and the second PCB, defining an internal volume between the first PCB and the second PCB;
a first electronic component disposed on the first surface of the first PCB, the first electronic component exposed to out of the PCB assembly;
a second electronic component, disposed on the second surface of the first PCB, occupying a first region of the internal volume; and
a thermal interface material (TIM) positioned in the internal volume,
wherein the second PCB defines a first opening, corresponding to a second region of the internal volume different from the first region of the internal volume occupied by the second electronic component, for insertion of a nozzle for injection of the TIM.
